(19) United States
(12) Patent Application Publication
(10) Pub. No.: US 2024/0040868 A1
(43) Pub. Date: Feb. 1, 2024

(54) DISPLAY PANEL

(71) Applicant: SAMSUNG DISPLAY CO., LTD., Yongin-si (KR)

(72) Inventors: Seunghwan CHO, Yongin-si (KR); Sangwoo KIM, Yongin-si (KR)

(21) Appl. No.: 18/226,005

(22) Filed: Jul. 25, 2023

(30) Foreign Application Priority Data
Jul. 26, 2022 (KR) 10-2022-0092642

(51) Int. Cl. H10K 59/131; H10K 59/121

(52) U.S. Cl. CPC H10K 59/131; H10K 59/121

(57) ABSTRACT

A display panel includes: a first input line arranged in a first corner area; a second input line arranged in a second corner area; a third input line connecting the first input line to the second input line, and a driving circuit arranged in the second corner area, connected to the second input line, and configured to supply electrical signals to a first pixel circuit arranged in the first corner area and a second pixel circuit arranged in the second corner area.

This application claims priority to Korean Patent Application No. 10-2022-0092642, filed on Jul. 26, 2022, and all the benefits accruing therefrom under 35 U.S.C. § 119, the content of which in its entirety is herein incorporated by reference.

### BACKGROUND

### 1. Field

One or more embodiments relate to a display panel and a display apparatus. One or more embodiments relate to a display panel and a display apparatus with bent edges.

### 2. Description of the Related Art

As the parts driving a display apparatus have been miniaturized, the proportion of the display apparatus in an electronic apparatus has gradually increased and a structure that may be bent to form a preset angle with respect to a flat state is also under development.

### SUMMARY

One or more embodiments include a display panel and a display apparatus with an improved visibility of a corner area.

Additional aspects will be set forth in part in the description which follows and, in part, will be apparent from the description, or may be learned by practice of the presented embodiments of the disclosure.

According to one or more embodiments, a display panel includes: a substrate including a main display area and a corner area extending from a corner of the main display area, where the corner area includes a first corner area and a second corner area, the first corner area is adjacent to the main display area, and the second corner area is outside the first corner area; a first input line arranged in the first corner area; a second input line arranged in the second corner area; a third input line connecting the first input line to the second input line; a first pixel circuit and a first display element connected to the first pixel circuit, each arranged in the first corner area; a second pixel circuit and a second display element connected to the second pixel circuit, each arranged in the second corner area; and a driving circuit arranged in the second corner area, connected to the second input line, and configured to supply electrical signals to the first pixel circuit and the second pixel circuit.

The second corner area may include a plurality of extension areas apart from each other, each of the plurality of extension areas may be divided into a first extension area and a second extension area, and the driving circuit may be arranged in the first extension area.

The first extension area may be between the first corner area and the second extension area.

A resolution of the first extension area may be less than a resolution of the first corner area and be equal to a resolution of the second extension area.

A resolution of the main display area may be equal to the resolution of the first corner area.

Arrangement of the first display element in the first corner area may be the same as arrangement of a display element in the main display area and the same as or different from arrangement of the second display element in the extension area.

The second extension area may be between the first corner area and the first extension area.

A resolution of the first extension area may be less than a resolution of the first corner area, and a resolution of the second extension area may be equal to the resolution of the first corner area.

A resolution of the main display area may be equal to the resolution of the first corner area.

Arrangement of the first display element in the first corner area may be the same as arrangement of a display element in the main display area, the same as arrangement of the second display element in the second extension area, and the same as or different from arrangement of the second display element in the first extension area.

A plurality of second display elements may be arranged in the extension area, and pixel electrodes of some of the plurality of second display elements arranged in the first extension area may be electrically connected to each other.

The first input line may be disposed in the same layer as the second input line and disposed in a layer different from the third input line.

The first display element may overlap the first input line.

The second display element may overlap the driving circuit.

The second display element may overlap the second input line.

A plurality of first display elements may be arranged in the first corner area, and pixel electrodes of some of the plurality of first display elements arranged in the first corner area may be electrically connected to each other.

According to one or more embodiments, a display panel includes a first display area and a second display area, where the first display area includes a central area, a first area, and a second area, the first area is adjacent to the central area in a first direction, and the second area is adjacent to the central area in a second direction crossing the first direction, and the second display area includes a corner area between the first area and the second area, the corner area includes a first corner area and a second corner area, the first corner area is adjacent to the first display area, and the second corner area is outside the first corner area. The display panel includes: a first input line arranged in a peripheral area and the first corner area, where the peripheral area is outside the first area; a second input line arranged in the second corner area; a third input line connecting the first input line to the second input line; a first driving circuit arranged in the peripheral area, connected to the first input line, and configured to supply electrical signals to a pixel circuit in the first display area; and a second driving circuit arranged in the second corner area, connected to the second input line, and configured to supply electrical signals a pixel circuit in the first corner area, and a pixel circuit in the second corner area.

The second corner area may include a plurality of extension areas apart from each other, each of the plurality of extension areas may be divided into a first extension area and a second extension area, and the second driving circuit may be arranged in the first extension area.

The first extension area may be between the first corner area and the second extension area.

The second extension area may be between the first corner area and the first extension area.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIG. 2A is a cross-sectional view of the display apparatus of FIG. 1, taken along line I-I′;

FIG. 2B is a cross-sectional view of the display apparatus of FIG. 1, taken along line II-II′;

FIG. 2C is a cross-sectional view of the display apparatus of FIG. 1, taken along line III-III′;

FIG. 3 is a plan view of a display panel according to an embodiment;

FIGS. 4A and 5A are circuit diagrams of a pixel according to an embodiment;

FIGS. 4B and 5B are schematic configuration views of a display panel according to an embodiment;

FIGS. 6 and 7 are schematic enlarged views of a region E of FIG. 3 according to an embodiment;

FIGS. 8A and 8B are schematic circuit diagrams of a driving circuit according to an embodiment;

FIG. 9 is a schematic enlarged view of a region F of FIG. 6;

FIG. 10 is a schematic enlarged view of a region G of FIG. 6;

FIG. 11 is a schematic enlarged view of a region F of FIG. 7;

FIG. 12 is a schematic enlarged view of a region G of FIG. 7;

FIG. 13 is a schematic view of a driving circuit and an input line according to an embodiment;

FIG. 14 is a cross-sectional view of the region F taken along lines A-A′ and B-B′ of FIG. 9;

FIG. 15 is a cross-sectional view of the region F taken along line C-C′ of FIG. 9;

FIG. 16 is a cross-sectional view of the region F taken along line D-D′ of FIG. 9;

FIGS. 17 to 19 are schematic views of an input line in a corner area;

FIGS. 20 and 21 are schematic views of a portion of a display panel; and

FIGS. 22 and 23 are schematic views of pixels in a driving circuit area of FIGS. 20 and 21.

### DETAILED DESCRIPTION

Reference will now be made in detail to embodiments, examples of which are illustrated in the accompanying drawings, where like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, where like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

In the case where a certain embodiment may be implemented differently, a specific process order may be performed in the order different from the described order. As an example, two processes successively described may be simultaneously performed substantially and performed in the opposite order.

It will be understood that when a layer, region, or element is referred to as being “connected” to another layer, region, or element, it may be “directly connected” to the other layer, region, or element or may be “indirectly connected” to the other layer, region, or element with other layer, region, or element interposed therebetween. For example, it will be understood that when a layer, region, or element is referred to as being “electrically connected” to another layer, region, or element, it may be “directly electrically connected” to the other layer, region, or element or may be “indirectly electrically connected” to other layer, region, or element with other layer, region, or element interposed therebetween.

In the present specification, “A and/or B” means A or B, or A and B. In the present specification, “at least one of A and B” means A or B, or A and B.

As used herein, “in a plan view” means that an objective portion is viewed from above (i.e., view in z direction), and “in a cross-sectional view” means that a cross-section of an objective portion taken vertically is viewed from a lateral side. As used herein, when it is referred that a first element “overlaps” a second element, the first element is arranged above or below the second element.

A display apparatus may be used as a display screen of various products including televisions, notebook computers, monitors, advertisement boards, Internet of things (“IoTs”) device as well as portable electronic apparatuses including mobile phones, smart phones, tablet personal computers (“PCs”), mobile communication terminals, electronic organizers, electronic books, portable multimedia players (“PMPs”), navigations, and ultra mobile personal computers (“UMPCs”). In addition, the display apparatus according to an embodiment may be used in wearable devices including smartwatches, watchphones, glasses-type displays, and head-mounted displays (“HMDs”). In addition, in an embodiment, the display apparatus may be used as instrument panels for automobiles, center fascias for automobiles, or center information displays (“CIDs”) disposed on a dashboard, room mirror displays that replace side mirrors of automobiles, and displays disposed on the backside of front seats as an entertainment for back seats of automobiles.

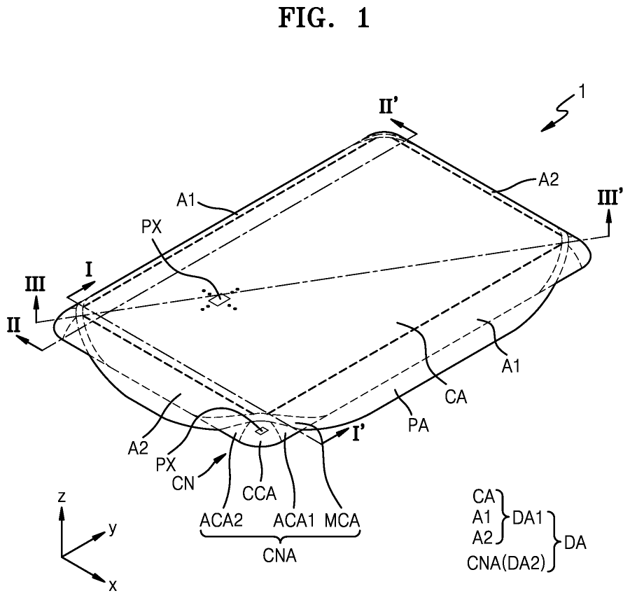

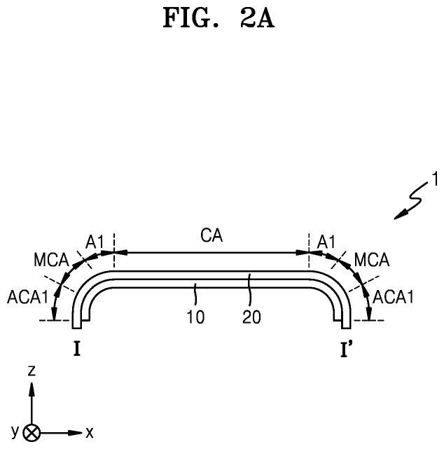

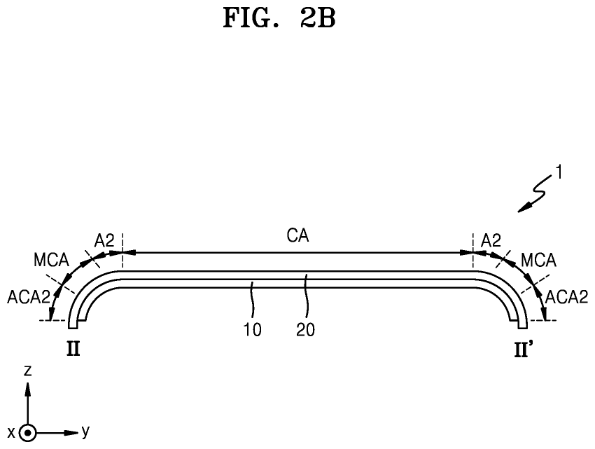

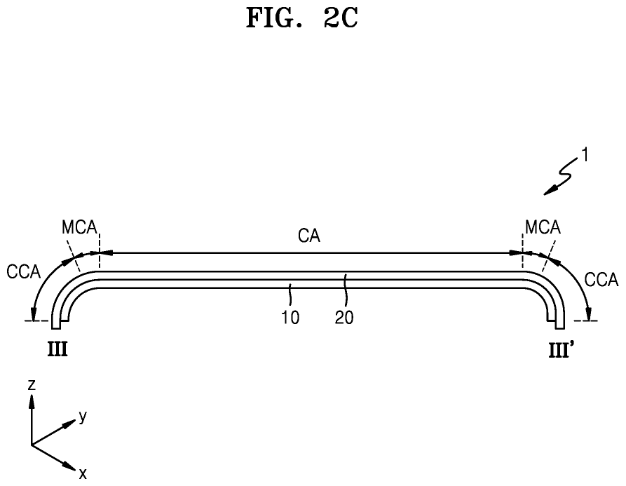

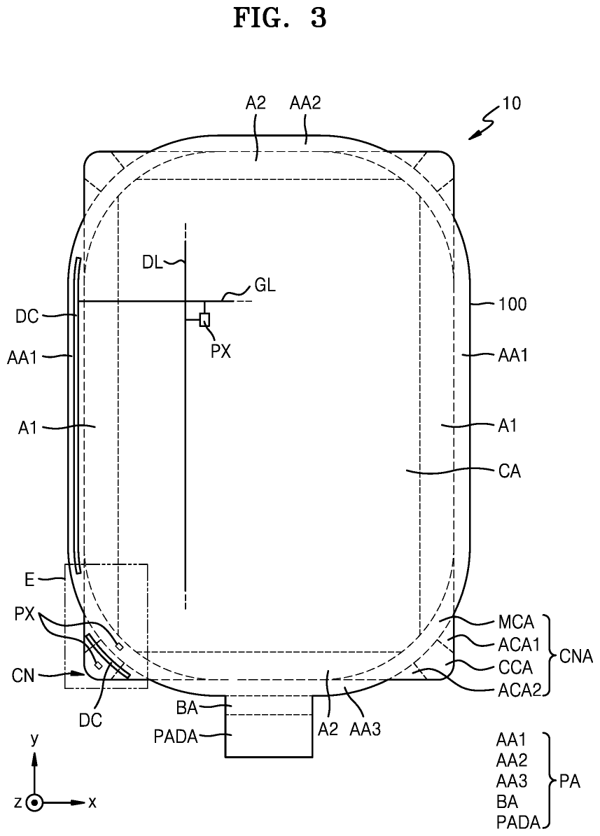

FIG. 1 is a schematic perspective view of a display apparatus 1 according to an embodiment. FIG. 2A is a cross-sectional view of the display apparatus 1 of FIG. 1, taken along line I-I′. FIG. 2B is a cross-sectional view of the display apparatus 1 of FIG. 1, taken along line II-II′. FIG. 2C is a cross-sectional view of the display apparatus 1 of FIG. 1, taken along line III-III′. FIG. 3 is a schematic plan view of a display panel 10 according to an embodiment. FIG. 1 is a perspective view of the display apparatus 1 that is bent, and FIG. 3 is a plan view of the display panel 10 that is unbent.

Referring to FIGS. 1 to 3, the display apparatus 1 may have edges in a first direction and edges in a second direction. Here, the first direction and the second direction may be directions crossing each other. As an example, the first direction may form an acute angle with respect to the second direction. As another example, the first direction may form an obtuse angle with respect to the second direction or be perpendicular to the second direction. Hereinafter, the case where the first direction is perpendicular to the second direction is mainly described in detail. As an example, the first direction may be an x direction or a −x direction, and the second direction may be a y direction or a −y direction. A third direction perpendicular to the first direction and the second direction may be a z direction or a −z direction.

The display apparatus 1 may include the display panel 10 and a cover window 20.

The display panel 10 may include the display area DA and the peripheral area PA. The display area DA may include a first display area DA1 and a second display area DA2. The display area DA and the peripheral area PA may be defined in the substrate 100 of the display panel 10. That is, the substrate 100 may include the display area DA and the peripheral area PA. The first display area DA1 may be a “main display area” of the display apparatus 1, and the second display area DA2 may be a “corner area” CNA extending from the corner of the first display area DA1.

The first display area DA1 may include a central area CA, a first area A1, and a second area A2, where the central area CA has a flat plane-shape, and the first area A1 and the second area A2 are lateral display areas adjacent to the central area CA.

The first area A1 may be adjacent to the central area CA in the first direction. The first area A1 may extend in the first direction from the edge of the second direction of the central area CA and bend. The first area A1 may be a region bent from the boundary between the first area A1 and the central area CA in a cross-section (e.g., an xz cross-section) in the first direction. It is shown in FIG. 2A that a first area A1 extending in the x direction from the central area CA and bending has the same curvature as a curvature of a first area A1 extending in the −x direction from the central area CA and bending. In another embodiment, the first area A1 extending in the x direction from the central area CA and bending may have a curvature different from a curvature of the first area A1 extending in the −x direction from the central area CA and bending.

The second area A2 may be adjacent to the central area CA in the second direction. The second area A2 may extend in the second direction from the edge of the first direction of the central area CA and bending. The second area A2 may be a region bent from the boundary between the second area A2 and the central area CA in a cross-section (e.g., an yz cross-section) in the second direction. It is shown in FIG. 2B that a second area A2 extending in the y direction from the central area CA and bending has the same curvature as a curvature of a second area A2 extending in the −x direction from the central area CA and bending. In another embodiment, the second area A2 extending in the y direction from the central area CA and bending may have a curvature different from a curvature of the second area A2 extending in the −y direction from the central area CA and bending.

The corner area CNA may be a region arranged in a corner CN of the display apparatus 1. In an embodiment, the corner area CNA may be a region where an edge of the first direction meets an edge of the second direction of the display apparatus 1. The corner area CNA may be a region between the first area A1 and the second area A2. In an embodiment, the corner CN may have a preset curvature. In the case where the first area A1 extends in the first direction and bends, and the second area A2 extends in the second direction and bends, at least a portion of the corner area CNA may extend in the first direction and bend and extend in the second direction and bend. At least a portion of the corner area CNA may be a region in which a plurality of curvatures in a plurality of directions overlap each other in a plan view. The corner area CNA may be provided in plurality. FIGS. 1 to 3 show four corner areas CNA.

The corner area CNA may include a first corner area and a second corner area outside the first corner area, where the first corner area is adjacent to the first display area DA1. The first corner area may include an intermediate area MCA. The second corner area may include a central corner area CCA, a first adjacent area ACA1, and a second adjacent area ACA2.

The central corner area CCA may extend in the first direction and the second direction and bend. The central corner area CCA may be bent in a cross-section (e.g., an xz cross-section) in the first direction and a cross-section (e.g., an yz cross-section) in the second direction. The central corner area CCA may be a region in which curvatures in a plurality of directions overlap each other in a plan view. The central corner area CCA may be arranged between the first adjacent area ACA1 and the second adjacent area ACA2.

The first adjacent area ACA1 may be adjacent to the central corner area CCA. In an embodiment, the first adjacent area ACA1 may be arranged between the central corner area CCA and the first area A1. That is, at least a portion of the first area A1 may be arranged between the central area CA and the first adjacent area ACA1 in the first direction. The first adjacent area ACA1 may be defined as the corner area CNA bent in a cross-section (e.g., the xz cross-section) in the first direction and substantially not bent in a cross-section (e.g., the yz cross-section) in the second direction.

The second adjacent area ACA2 may be adjacent to the central corner area CCA. In an embodiment, the second adjacent area ACA2 may be arranged between the central corner area CCA and the second area A2. That is, at least a portion of the second area A2 may be arranged between the central area CA and the second adjacent area ACA2 in the second direction. The second adjacent area ACA2 may be defined as the corner area CNA bent in a cross-section (e.g., the yz cross-section) in the second direction and substantially not bent in a cross-section (e.g., the yz cross-section) in the first direction.

The intermediate area MCA may be adjacent to the first display area DA1. The intermediate area MCA may be arranged between the central area CA and the central corner area CCA. In an embodiment, the intermediate area MCA may extend between the first area A1 and the first adjacent area ACA1. In an embodiment, the intermediate area MCA may extend between the second area A2 and the second adjacent area ACA2. In an embodiment, the intermediate area MCA may be bent.

A plurality of pixels PX may be arranged in at least one of the central area CA, the first area A1, the second area A2, and the corner area CNA. Each of the plurality of pixels PX may be connected to a gate line GL and a data line DL and may include a display element. In an embodiment, the display element may be an organic light-emitting diode including an organic emission layer. Alternatively, the display element may be a light-emitting diode LED including an inorganic emission layer. The size of the light-emitting diode LED may be microscale or nanoscale. As an example, the light-emitting diode may be a micro light-emitting diode. Alternatively, the light-emitting diode may be a nanorod light-emitting diode. The nanorod light-emitting diode may include gallium nitride (GaN). In an embodiment, a color-converting layer may be disposed on the nano-rod light-emitting diode. The color-converting layer may include quantum dots. Alternatively, the display element may be a quantum-dot light-emitting diode including a quantum-dot emission layer.

Each of the pixels PX may be configured to emit light of a preset color by using the display element. In the present specification, the pixel PX is a minimum unit implementing images and may denote an emission area. Accordingly, in the present specification, the arrangement of the pixels may denote the arrangement of the display elements or the arrangement of the emission areas. In the case where the organic light-emitting diode is employed as the display element, the emission area may be defined by an opening of a pixel-defining layer. This is described below.

The peripheral area PA may be arranged outside the first display area DA1. The pixel PX may not be arranged in the peripheral area PA. Accordingly, the peripheral area PA may be a non-display area that does not display images. The peripheral area PA may include a first peripheral area AA1, a second peripheral area AA2, a third peripheral area AA3, a bent area BA, and a pad area PADA.

The first peripheral area AA1 may be arranged outside the first area A1. The first area A1 may be arranged between the first peripheral area AA1 and the central area CA. The central area CA may be arranged between a pair of first peripheral areas AA1 facing each other. In an embodiment, the first peripheral area AA1 may extend in the first direction from the first area A1.

The second peripheral area AA2 may be arranged outside the second area A2 in the upper side, and the second area A2 in the upper side may be arranged between the second peripheral area AA2 and the central area CA. The third peripheral area AA3 may be arranged outside the second area A2 in the lower side, and the second area A2 in the lower side may be arranged between the third peripheral area AA3 and the central area CA. The second peripheral area AA2 and the third peripheral area AA3 may each extend in the second direction. The central area CA may be arranged between the second peripheral area AA2 and the third peripheral area AA3.

A driving circuit DC and input lines may be arranged in the peripheral area PA and the corner area CNA, where the driving circuit DC is configured to provide electrical signals to the pixels PX, and the input lines are configured to provide electrical signals to the driving circuit DC. In an embodiment, the driving circuit DC may be a gate driving circuit configured to provide gate signals to the pixel PX. The input lines may include at least one clock line and at least one voltage line, where the at least one clock line is configured to supply at least one clock signal, and the at least one voltage line is configured to supply at least one voltage signal. In an embodiment, the driving circuit DC may be a data driving circuit configured to provide data signals to the pixel PX through the data line DL. A power line may be further arranged in the peripheral area PA and the corner area CNA, where the power line is configured to provide power. In an embodiment, the driving circuit DC and/or the input lines may be arranged in the first peripheral area AA1, the central corner area CCA, the first adjacent area ACA1, and the second adjacent area ACA2.

The bent area BA may be arranged outside the second area A2. The bent area BA may be arranged outside the third peripheral area AA3. The third peripheral area AA3 may be arranged between the bent area BA and the central area CA. The display panel 10 may be bent in the bent area BA. In this case, the pad area PADA may face the rear surface of the display panel 10 opposite the upper surface configured to display images. Accordingly, the pad area PADA may not be viewed by users.

The pad area PADA may be disposed outside the bent area BA. The bent area BA may be arranged between the third peripheral area AA3 and the pad area PADA. A pad (not shown) may be arranged in the pad area PADA. At least one of a driving chip and a printed circuit board electrically connected to the pad area PADA through the pad may be arranged in the pad area PADA. The display panel 10 may be configured to receive electrical signals and/or a power voltage from the driving chip and the printed circuit board through the pad. At least one of the driving chip and the printed circuit board may be electrically connected to the pad through anisotropic conductive film. The driving chip may include an integrated circuit (“IC”). The printed circuit board may include a flexible printed circuit board (“FPCB”) or a rigid printed circuit board (“PCB”). In an embodiment, the data driving circuit may be disposed on at least one of the driving chip and the printed circuit board.

The cover window 20 may be disposed on the display panel 10. The cover window 20 may be configured to protect the display panel 10. In an embodiment, the cover window 20 may be a flexible window. The cover window 20 may include glass, sapphire, or plastic. The cover window 20 may be, for example, ultra-thin glass or colorless polyimide. The cover window 20 may be attached to the display panel 10 by using a transparent adhesive member such as an optically clear adhesive (“OCA”).

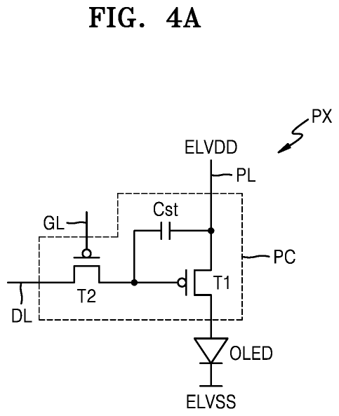

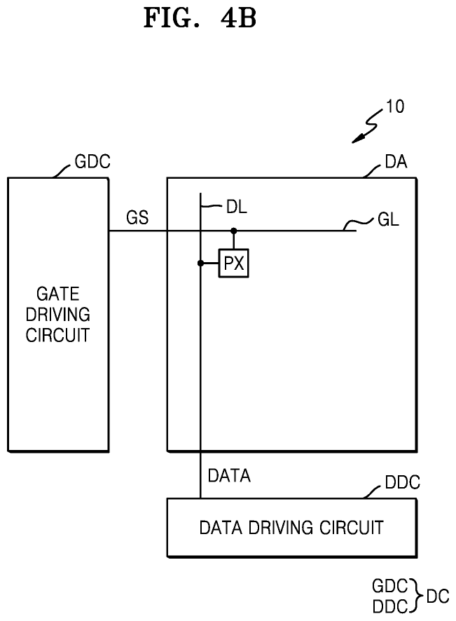

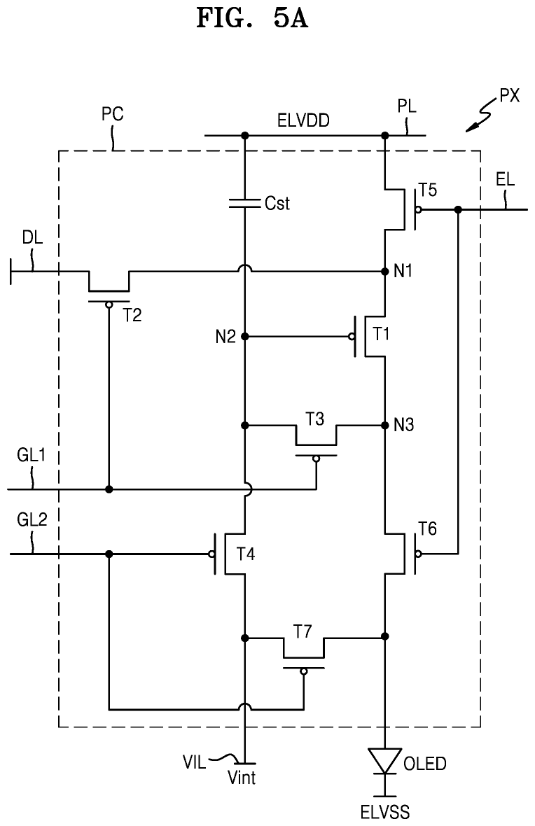

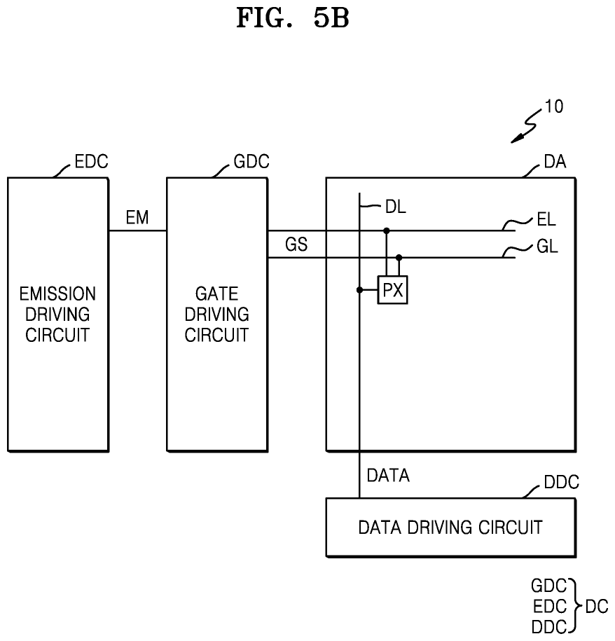

FIGS. 4A and 5A are circuit diagrams of a pixel according to an embodiment. FIGS. 4B and 5B are schematic configuration views of the display panel 10 according to an embodiment.

Referring to FIG. 4A, the pixel PX includes a pixel circuit PC and an organic light-emitting diode OLED connected to the pixel circuit PC. The pixel circuit PC may include a first transistor T1, a second transistor T2, and a capacitor Cst. Each pixel PX may be configured to emit, for example, red, green, blue, or white light by using the organic light-emitting diode OLED. The first transistor T1 and the second transistor T2 may each be implemented as thin-film transistors.

The second transistor T2 is a switching transistor, may be connected to the gate line GL and the data line DL, and configured to transfer a data signal to the first transistor T1 in response to a gate signal, the data signal being input from the data line DL, and the gate signal being input from the gate line GL. The capacitor Cst may be connected to the second transistor T2 and a driving voltage line PL and configured to store a voltage corresponding to a difference between a voltage corresponding to the data signal transferred from the second transistor T2 and driving voltage ELVDD supplied to the driving voltage line PL.

The first transistor T1 is a driving transistor, may be connected to the driving voltage line PL and the capacitor Cst, and configured to control a driving current according to the voltage stored in the capacitor Cst, the driving current flowing from the driving voltage line PL to the organic light-emitting diode OLED. The organic light-emitting diode OLED may emit light having a preset brightness corresponding to the driving current. An opposite electrode of the organic light-emitting diode OLED may be configured to receive a common voltage ELVSS.

Referring to FIG. 4B, the plurality of pixels PX and signal lines may be located in the display area DA, where the signal lines may be configured to apply electrical signals to the plurality of pixels PX. The signal lines that may be configured to apply electrical signals to each of the pixels PX may include a plurality of data lines DL and a plurality of gate lines GL.

The driving circuit DC may be located outside the display area DA, where the driving circuit DC is configured to supply signals for driving the pixels PX. The driving circuit DC may include a gate driving circuit GDC and a data driving circuit DDC. In an embodiment, the gate driving circuit GDC may be arranged in the first peripheral area AA1, the central corner area CCA, the first adjacent area ACA1, and the second adjacent area ACA2. The gate driving circuit GDC may be arranged along the edge of the first display area DA1, for example, the first area A1 and the intermediate area MCA. The gate driving circuit GDC may be connected to the gate lines GL and configured to output gate signals GS to the gate lines GL. The data driving circuit DDC may be arranged in the pad area PADA. The data driving circuit DDC may be connected to the data lines DL and configured to output data signals DATA to the data lines DL.

Though it is described with reference to FIG. 4A that the pixel circuit PC includes two transistors and one capacitor, the embodiment is not limited thereto. The number of thin-film transistors and the number of capacitors may be variously changed according to the design of the pixel circuit PC in another embodiment.

Referring to FIG. 5A, the pixel circuit PC may include the first transistor T1, which is the driving transistor, and second to seventh transistors T2, T3, T4, T5, T6, and T7, which are switching transistors. Depending on the type (P-type or N-type) and/or an operation condition of a transistor, a first terminal of each of the first to seventh transistors T1, T2, T3, T4, T5, T6, and T7 may be a source terminal or a drain terminal, and a second terminal may be a terminal different from the first terminal. As an example, in the case where the first terminal is a source terminal, the second terminal may be a drain terminal.

In an embodiment, the source terminal and the drain terminal may be referred to as a source electrode and a drain electrode interchangeably, respectively.

The pixel circuit PC may be connected to a first gate line GL1, a second gate line GL2, an emission control line EL, a data line DL, the driving voltage line PL, and an initialization voltage line VIL, where the first gate line GL1 is configured to transfer first gate signals, the second gate line GL2 is configured to transfer second gate signals, the emission control line EL is configured to transfer emission control signals, the data line DL is configured to transfer data signals, the driving voltage line PL is configured to transfer the driving voltage ELVDD, and the initialization voltage line VIL is configured to transfer an initialization voltage Vint.

The first transistor T1 may be connected between the driving voltage line PL and the organic light-emitting diode OLED. The first transistor T1 may be connected to the driving voltage line PL through the fifth transistor T5, and electrically connected to the organic light-emitting diode OLED through the sixth transistor T6. The first transistor T1 includes a gate, a first terminal, and a second terminal, where the gate is connected to a second node N2, the first terminal is connected to a first node N1, and the second terminal is connected to a third node N3. The first transistor T1 may be configured to receive a data signal according to a switching operation of the second transistor T2 and supply a driving current to the organic light-emitting diode OLED.

The second transistor T2 (a data-write transistor) may be connected between the data line DL and the first node N1 and connected to the driving voltage line PL through the fifth transistor T5. The first node N1 may be a node to which the first transistor T1 and the fifth transistor T5 are connected. The second transistor T2 may include a gate, a first terminal, and a second terminal, where the gate is connected to the first gate line GL1, the first terminal is connected to the data line DL, and the second terminal is connected to the first node N1 (or the first terminal of the first transistor T1). The second transistor T2 may be turned on according to a first gate signal transferred through the first gate line GL1 and configured to perform a switching operation of transferring a data signal to the first node N1, where the data signal is transferred through the data line DL.

The third transistor T3 (a compensation transistor) may be connected between the second node N2 and the third node N3. The third transistor T3 may be connected to the organic light-emitting diode OLED through the sixth transistor T6. The second node N2 may be a node to which a gate of the first transistor T1 is connected, and the third node N3 may be a node to which the first transistor T1 and the sixth transistor T6 are connected. The third transistor T3 may include a gate, a first terminal, and a second terminal, where the gate is connected to the first gate line GL1, the first terminal is connected to the second node N2 (or the gate of the first transistor T1), and the second terminal is connected to the third node N3 (or the second terminal of the first transistor T1). The third transistor T3 may be turned on according to a first gate signal and may compensate for a threshold voltage of the first transistor T1 by diode-connecting the first transistor T1, where the first gate signal is transferred through the first gate line GL1.

The fourth transistor T4 (a first initialization transistor) may be connected between the second node N2 and the initialization voltage line VIL. The fourth transistor T4 may include a gate, a first terminal, and a second terminal, where the gate is connected to the second gate line GL2, the first terminal is connected to the second node N2, and the second terminal is connected to the initialization voltage line VIL. The fourth transistor T4 may be turned on according to a second gate signal to initialize the gate voltage of the first transistor T1 by transferring the initialization voltage Vint to the gate of the first transistor T1, where the second gate signal is transferred through the second gate line GL2.

The fifth transistor T5 (a first emission control transistor) may be connected between the driving voltage line PL and the first node N1. The sixth transistor T6 (a second emission control transistor) may be connected between the third node N3 and the organic light-emitting diode OLED. The fifth transistor T5 may include a gate, a first terminal, and a second terminal, where the gate is connected to the emission control line EL, the first terminal is connected to the driving voltage line PL, and the second terminal is connected to the first node N1. The sixth transistor T6 may include a gate, a first terminal, and a second terminal, where the gate is connected to the emission control line EL, the first terminal is connected to the third node N3, and the second terminal is connected to a pixel electrode of the organic light-emitting diode OLED. The fifth transistor T5 and the sixth transistor T6 may be simultaneously turned on according to an emission control signal, and the driving current may flow through the organic light-emitting diode OLED, where the emission control signal is transferred through the emission control line EL.

The seventh transistor T7 (a second initialization transistor) may be connected between the organic light-emitting diode OLED and the initialization voltage line VIL. The seventh transistor T7 may include a gate, a first terminal, and a second terminal, where the gate is connected to the second gate line GL2, the first terminal is connected to the second terminal of the sixth transistor T6 and the pixel electrode of the organic light-emitting diode OLED, and the second terminal is connected to the initialization voltage line VIL. The seventh transistor T7 may be turned on according to a second gate signal to initialize the voltage of the pixel electrode of the organic light-emitting diode OLED by transferring the initialization voltage Vint to the pixel electrode of the organic light-emitting diode OLED, where the second gate signal is transferred through the second gate line GL2. In another embodiment, the gate of the seventh transistor T7 may be connected to a third gate line separate from the second gate line GL2. The seventh transistor T7 may be omitted.

The capacitor Cst may include a first electrode and a second electrode, where the first electrode is connected to the second node N2, and the second electrode is connected to the driving voltage line PL. The capacitor Cst may maintain a voltage applied to the gate of the first transistor T1 by storing and maintaining a voltage corresponding to a difference between voltages supplied to two opposite ends (i.e., the first electrode and the second electrode), respectively.

The organic light-emitting diode OLED may include the pixel electrode (e.g., an anode) and the opposite electrode (e.g., a cathode) facing the pixel electrode, where the opposite electrode may be configured to receive the common voltage ELVSS. The organic light-emitting diode OLED may be configured to display images by receiving the driving current from the first transistor T1 and emitting light of a preset color, where the driving current corresponds to a voltage stored in the capacitor Cst.

Referring to FIG. 5B, the plurality of pixels PX and signal lines may be located in the display area DA, where the signal lines may be configured to apply electrical signals to the plurality of pixels PX. The signal lines that may be configured to apply electrical signals to each of the pixels PX may include a plurality of data lines DL, a plurality of gate lines GL, and a plurality of emission control lines EL.

The driving circuit DC may be located outside the display area DA, where the driving circuit DC is configured to supply signals for driving the pixels PX. The driving circuit DC may include the gate driving circuit GDC, an emission driving circuit EDC, and the data driving circuit DDC. In an embodiment, the gate driving circuit GDC and the emission driving circuit EDC may be arranged in the first peripheral area AA1, the central corner area CCA, the first adjacent area ACA1, and the second adjacent area ACA2. The gate driving circuit GDC and the emission driving circuit EDC may be arranged adjacently in parallel along the edge of the first display area DA1, for example, the first area A1 and the intermediate area MCA. The gate driving circuit GDC may be connected to the gate lines GL and configured to output gate signals GS to the gate lines GL. The emission driving circuit EDC may be connected to the emission control lines EL and configured to output emission control signals EM to the emission control lines EL. The data driving circuit DDC may be arranged in the pad area PADA. The data driving circuit DDC may be connected to the data lines DL and configured to output data signals DATA to the data lines DL.

Though it is shown in FIGS. 4A and 5A that transistors of the pixel circuit PC are P-type transistors, the embodiment is not limited thereto. As another example, the transistors of the pixel circuit PC may be N-type transistors, or some may be P-type transistors, and others may be N-type transistors.

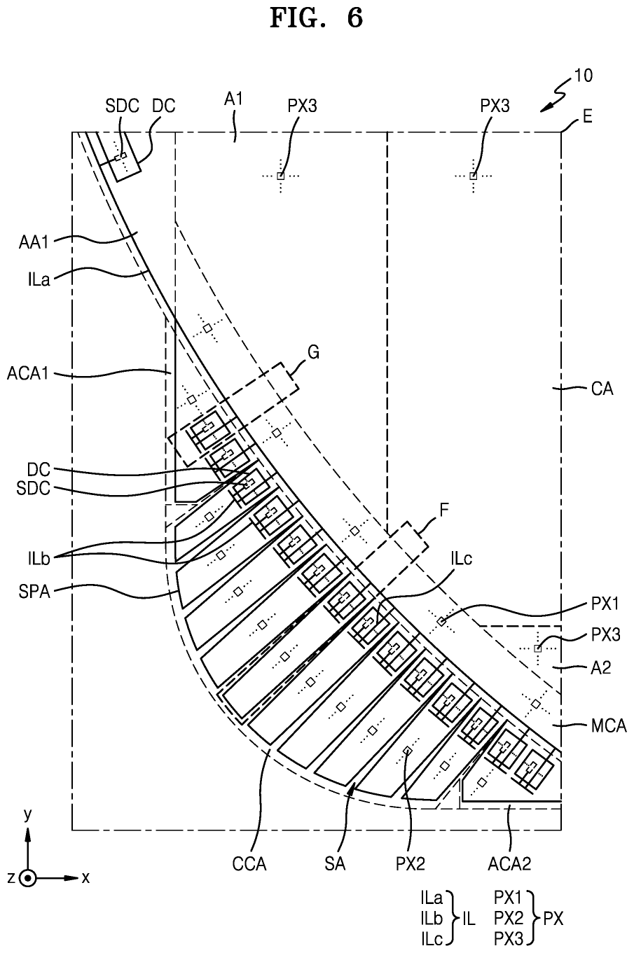

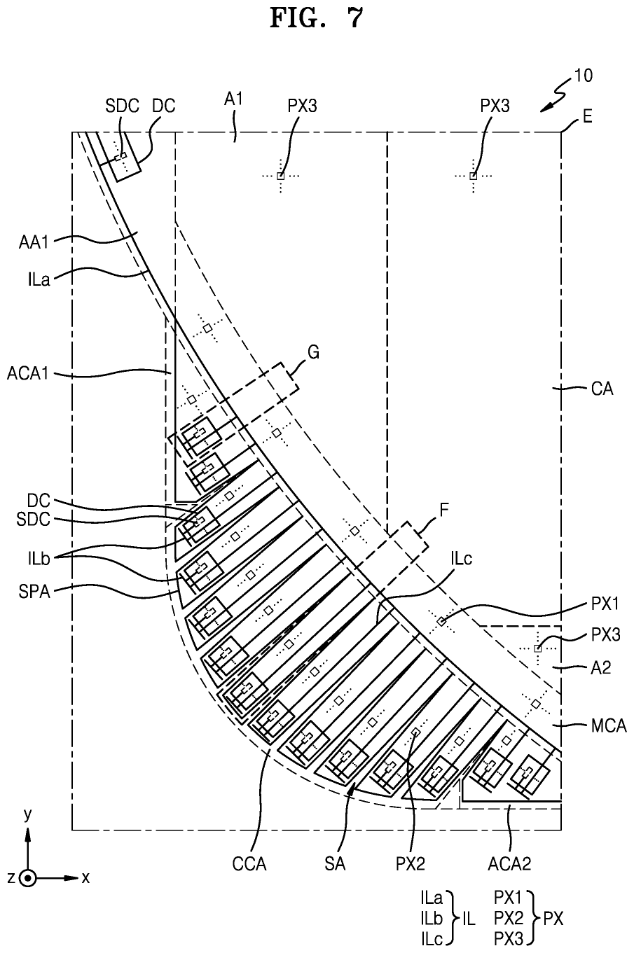

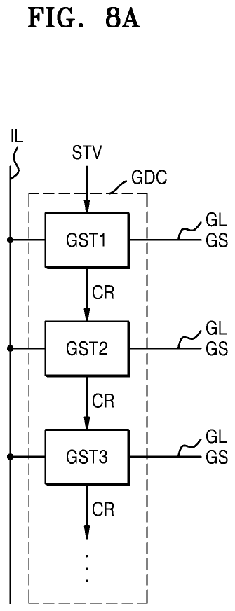

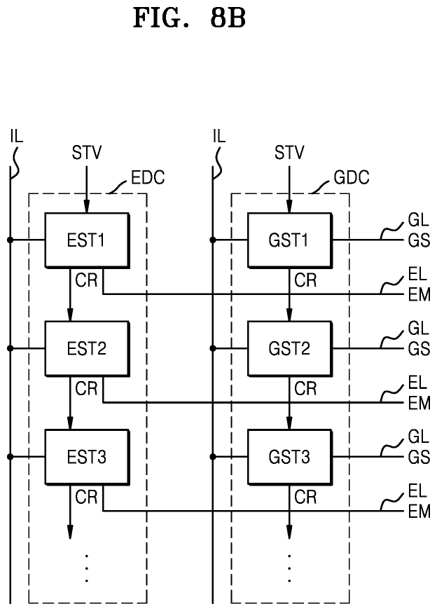

FIGS. 6 and 7 are schematic enlarged views of a region E of FIG. 3 according to an embodiment. FIGS. 8A and 8B are schematic circuit diagrams of a driving circuit according to an embodiment.

Referring to FIG. 6, the plurality of pixels PX may be arranged in the first display area DA1 and the second display area DA2 including the corner area CNA. The first display area DA1 may include the central area CA, the first area A1, and the second area A2. The corner area CNA may include the central corner area CCA, the first adjacent area ACA1, the second adjacent area ACA2, and the intermediate area MCA. Accordingly, the display panel 10 may be configured to display images in the first display area DA1 and the corner area CNA.

The central corner area CCA may include an extension area SPA having a straight line shape. In an embodiment, the central corner area CCA may include a plurality of extension areas SPA apart from each other. Each of the plurality of extension areas SPA may be a region starting from the boundary between the intermediate area MCA and the central corner area CCA and extending in a direction (referred to as an ‘extension direction of the extension area SPA’, hereinafter) away from the central area CA. In an embodiment, each of the plurality of extension areas SPA may extend in a preset direction between the first direction and the second direction.

A separation area SA may be defined between the adjacent extension areas SPA. The separation area SA may be a region in which elements of the display panel 10 are not arranged. When the central corner area CCA is bent, more compressive strain may occur than tensile strain in the central corner area CCA. In an embodiment, because the separation area SA is defined between the adjacent extension areas SPA, the central corner area CCA may contract. Accordingly, the display panel 10 may be bent without damage in the central corner area CCA.

The plurality of pixels PX may be arranged in a plurality of columns and a plurality of rows in the extension area SPA. A column in the extension area SPA may mean a line in the extension direction of the extension area SPA inside the extension area SPA. Columns in the extension area SPA may be parallel to each other. Intervals between adjacent columns in the extension area SPA may be identical. A resolution (unit: pixels per inch (ppi)) of the corner area CNA may be increased by arranging the pixels PX in two or more columns in the extension area SPA. Accordingly, a phenomenon that the first display area DA1 and the second display area DA2 are discriminated from each other and thus viewed different from each other may be reduced by reducing a difference in the resolution between the first display area DA1 and the second display area DA2.

The driving circuit DC may be arranged in the first peripheral area AA1, the central corner area CCA, the first adjacent area ACA1, and the second adjacent area ACA2. The driving circuit DC may include a plurality of sub-driving circuits SDC. The driving circuit DC may be connected to a plurality of input lines IL.

In an embodiment, as shown in FIG. 6, the plurality of sub-driving circuits SDC may be arranged along the edge of the first area A1 in the first peripheral area AA1, and arranged along the edge of the intermediate area MCA in the central corner area CCA, the first adjacent area ACA1, and the second adjacent area ACA2. The plurality of sub-driving circuits SDC may be arranged to be adjacent to a boundary between the intermediate area MCA and the central corner area CCA, a boundary between the intermediate area MCA and the first adjacent area ACA1, and a boundary between the intermediate area MCA and the second adjacent area ACA2. The sub-driving circuits SDC in the central corner area CCA, the first adjacent area ACA1, and the second adjacent area ACA2 may be arranged to surround at least a portion of the intermediate area MCA. Some of the pixels PX in the central corner area CCA, the first adjacent area ACA1, and the second adjacent area ACA2 may overlap the sub-driving circuits SDC in a plan view.

In another embodiment, as shown in FIG. 7, the sub-driving circuits SDC in the central corner area CCA, the first adjacent area ACA1, and the second adjacent area ACA2 may be arranged at the ends of the central corner area CCA, the first adjacent area ACA1, and the second adjacent area ACA2.

In an embodiment, the driving circuit DC may include a gate driving circuit GDC. Referring to FIG. 8A, the gate driving circuit GDC may be implemented by a shift register including a plurality of stages GST1, GST2, GST3, . . . . Each of the stages GST1, GST2, GST3, . . . may be a sub-driving circuit SDC. Each of the stages GST1, GST2, GST3, . . . may be connected to a gate line GL corresponding thereto, and configured to output a gate signal GS to the gate line GL corresponding thereto. A first stage GST1 may be configured to output a gate signal GS in response to an external start signal STV. The rest of the stages GST2, GST3, . . . except for the first stage GST1 may each be configured to receive a carry signal CR as a start signal, the carry signal CR being output from the previous stage. Each of the stages GST1, GST2, GST3, . . . may be connected to a plurality of input lines IL arranged outside the stages GST1, GST2, GST3, . . . .

In an embodiment, the driving circuit DC may include a plurality of driving circuits. As an example, the driving circuit DC may include a gate driving circuit GDC and an emission driving circuit EDC. Some of the input lines IL connected to the gate driving circuit GDC may be configured to input the same signal as a signal of some of the input lines IL connected to the emission driving circuit EDC.

Referring to FIG. 8B, the gate driving circuit GDC may be implemented by a shift register including a plurality of stages GST1, GST2, GST3, . . . . Each of the stages GST1, GST2, GST3, . . . may be a sub-driving circuit SDC. Each of the stages GST1, GST2, GST3, . . . may be connected to a gate line GL corresponding thereto, and configured to output a gate signal GS to the gate line GL corresponding thereto. A first stage GST1 may be configured to output a gate signal GS in response to an external start signal STV. The rest of the stages GST2, GST3, . . . except for the first stage GST1 may each be configured to receive a carry signal CR as a start signal, the carry signal CR being output from the previous stage. Each of the stages GST1, GST2, GST3, . . . may be connected to a plurality of input lines IL arranged outside the stages GST1, GST2, GST3, . . . .

The emission driving circuit EDC may be implemented by a shift register including a plurality of stages EST1, EST2, EST3, . . . . Each of the stages EST1, EST2, EST3, . . . may be a sub-driving circuit SDC. Each of the stages EST1, EST2, EST3, . . . may be connected to an emission control line EL corresponding thereto, and configured to output an emission control signal EM to an emission control line EL corresponding thereto. A first stage EST1 may be configured to output an emission control signal EM in response to an external start signal STV. The rest of the stages EST2, EST3, . . . except for the first stage EST1 may each be configured to receive a carry signal CR as a start signal, the carry signal CR being output from the previous stage. Each of the stages EST1, EST2, EST3, . . . may be connected to a plurality of input lines IL arranged outside the stages EST1, EST2, EST3, . . . .

The plurality of input lines IL may be signal lines including a plurality of voltage lines and a plurality of clock lines. For convenience of illustration, FIGS. 8A and 8B show only one input line IL.

In the gate driving circuit GDC of FIGS. 8A and 8B, though each of the stages GST1, GST2, GST3, . . . is connected to one gate line GL, this is provided as an example. Each of the stages GST1, GST2, GST3, . . . may be connected to one or more gate lines GL, and configured to output a gate signal GS to each gate line GL at a preset timing. As an example, each of the stages GST1, GST2, GST3, . . . is connected to a first gate line GL1 and a second gate line GL2 as shown in FIG. 5A and configured to output gate signals GS to the first gate line GL1 and the second gate line GL2 at different timings, respectively.

Referring to FIGS. 6 and 7 again, the input lines IL may include a first input line ILa, a second input line ILb, and a third input line ILc, where the third input line ILc connects the first input line ILa to the second input line ILb.

The first input line ILa may extend along the edges of the first peripheral area AA1 and the intermediate area MCA in the first peripheral area AA1 and the intermediate area MCA. The first input line ILa may extend to surround at least a portion of the central area CA, the first area A1, and the second area A2. The first input line ILa may be connected to the sub-driving circuits SDC arranged in the first peripheral area AA1. The first input line ILa may be arranged to be adjacent to the outside of the sub-driving circuits SDC.

The second input line ILb may be arranged in the central corner area CCA, the first adjacent area ACA1, and the second adjacent area ACA2. The second input line ILb may extend in a direction of surrounding the edge of the intermediate area MCA. The second input line ILb arranged in the first adjacent area ACA1, the second input line ILb arranged in the central corner area CCA, and the second input line ILb arranged in the second adjacent area ACA2 may be separated and may not be arranged in the separation area SA. The second input line ILb arranged in the central corner area CCA may extend in a direction (e.g., the width direction of the extension area SPA) perpendicular to an extension direction of each of the extension areas SPA in the central corner area CCA. The second input line ILb may be connected to the sub-driving circuits SDC arranged in the central corner area CCA, the first adjacent area ACA1, and the second adjacent area ACA2. The second input line ILb may be arranged to be adjacent to the outside of the sub-driving circuits SDC.

The third input line ILc may electrically connect the first input line ILa to the second input line ILb. The extension direction of the third input line ILc may be different from the extension direction of the first input line ILa and the second input line ILb. As an example, the third input line ILc may extend in a direction perpendicular to the extension direction of the first input line ILa and the second input line ILb. The third input line ILc may extend in a direction away from the intermediate area MCA.

The third input line ILc may be provided in plurality. The plurality of third input lines ILc may be arranged in the corner area CNA. The third input line ILc may extend from a portion of the first input line ILa in the intermediate area MCA, to the central corner area CCA, and be arranged in the extension areas SPA, respectively. The third input lines ILc may extend from a portion of the first input line ILa in the intermediate area MCA, to the first adjacent area ACA1, and be arranged in the first adjacent area ACA1. The third input lines ILc may extend from a portion of the first input line ILa in the intermediate area MCA, to the second adjacent area ACA2, and be arranged in the second adjacent area ACA2.

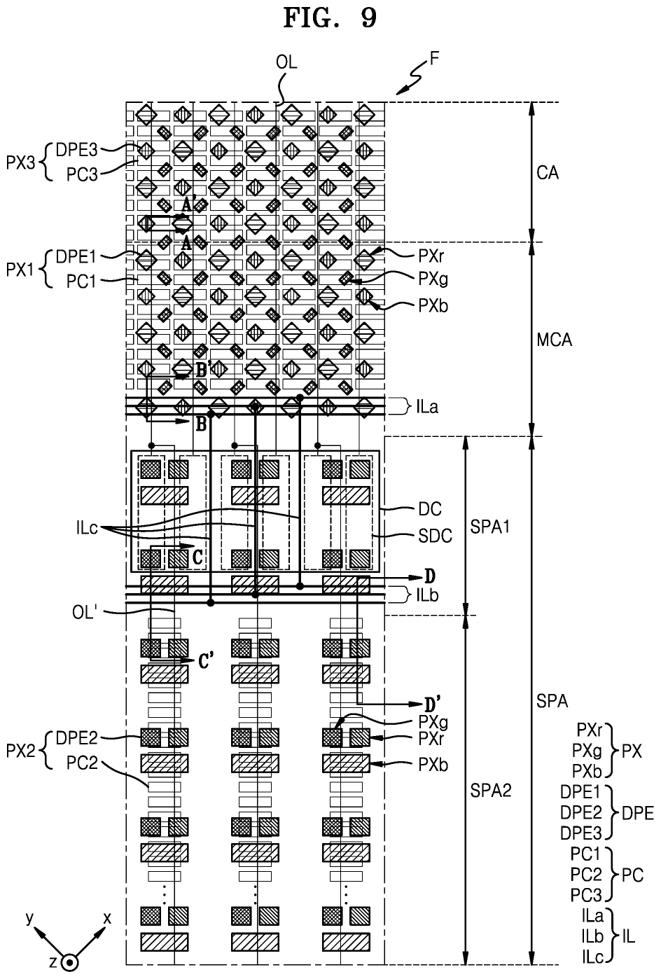

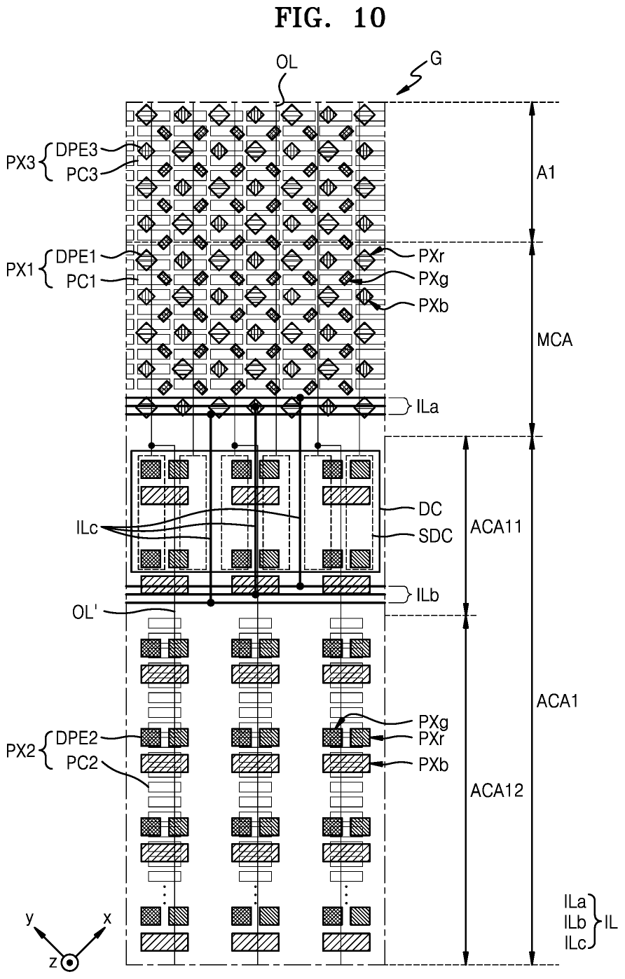

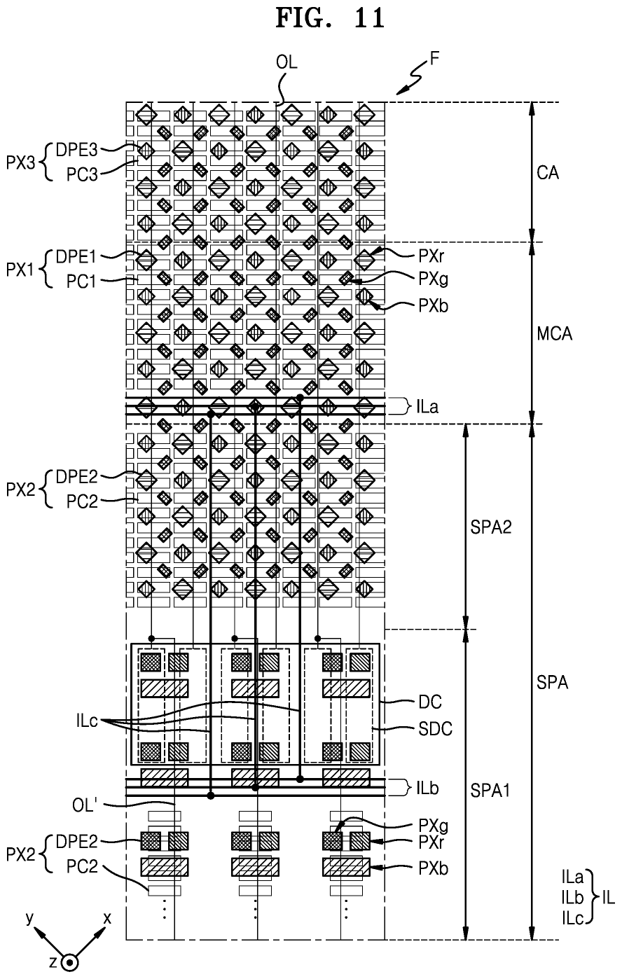

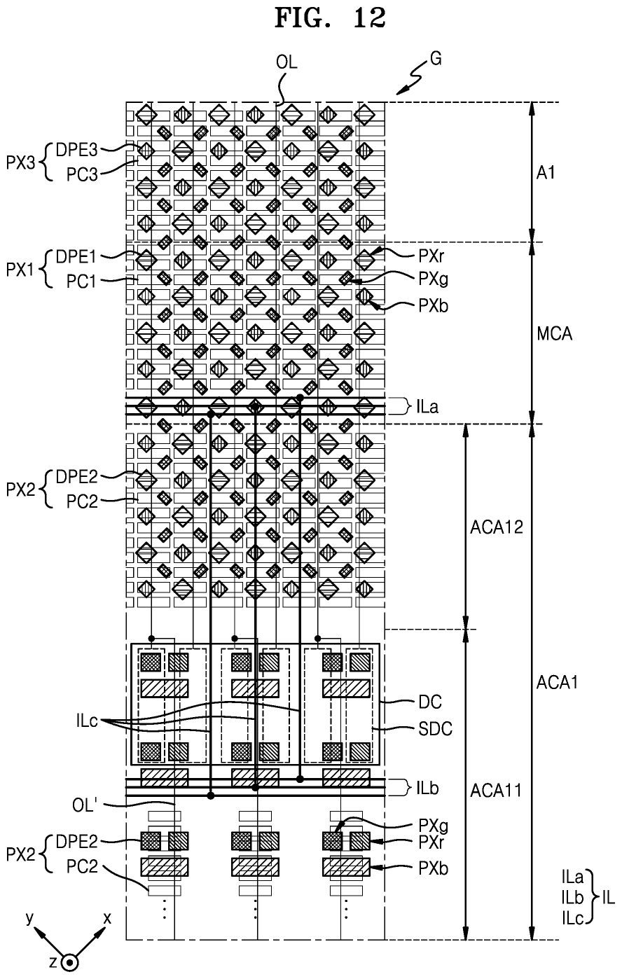

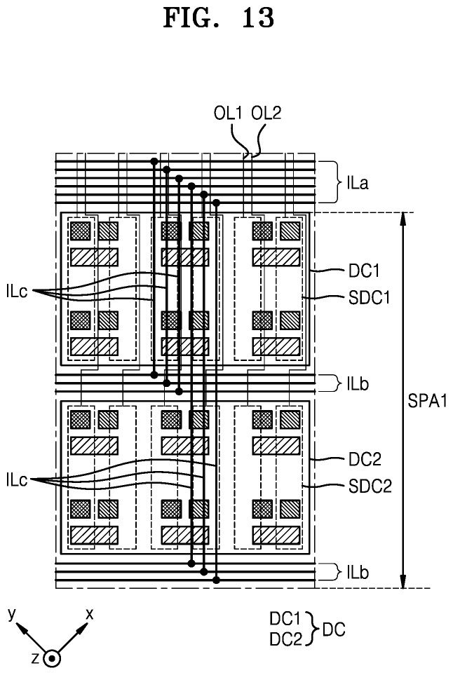

FIG. 9 is a schematic enlarged view of a region F of FIG. 6. FIG. 10 is a schematic enlarged view of a region G of FIG. 6. FIG. 11 is a schematic enlarged view of a region F of FIG. 7. FIG. 12 is a schematic enlarged view of a region G of FIG. 7. FIG. 13 is a schematic view of the driving circuit DC and an input line according to an embodiment.

Referring to FIGS. 9 to 12, the display panel 10 may include a substrate, the input line IL, the pixel circuit PC, the driving circuit DC, the gate line GL, and a display element DPE disposed over the substrate. The input line IL may include the first input line ILa, the second input line ILb, and the third input line ILc. The first input line ILa, the second input line ILb, an output line OL, and the third input line ILc may be signal lines configured to input/output/transfer signals. The substrate may include the central area CA, the first area A1, the intermediate area MCA, the central corner area CCA, and the first adjacent area ACA1. The central corner area CCA may include a plurality of extension areas SPA.

Though not shown, the substrate may include the second area A2 and the second adjacent area ACA2.

The first input line ILa may be arranged in the intermediate area MCA. The driving circuit DC and the second input line ILb may be arranged in a portion of the extension area SPA and a portion of the first adjacent area ACA1. The extension area SPA may be divided into a first extension area SPA1 and a second extension area SPA2, where the driving circuit DC is arranged in the first extension area SPA1. The first adjacent area ACA1 may be divided into a (1-1)st adjacent area ACA11 and a (1-2)nd adjacent area ACA12, where the driving circuit DC is arranged in the (1-1)st adjacent area ACA11. Similar to the first adjacent area ACA1, the second adjacent area ACA2 of the substrate may be divided into a (2-1)st adjacent area and a (2-2)nd adjacent area, where the driving circuit DC is arranged in the (2-1)st adjacent area. The second input line ILb may be arranged in the first extension area SPA1, the (1-1)st adjacent area ACA11, and the (2-1)st adjacent area. Hereinafter, because the arrangement of the elements in the second adjacent area ACA2 is similar to the arrangement of the elements in the first adjacent area ACA1, description thereof is omitted.

In an embodiment, as shown in FIG. 9, the first extension area SPA1 may be an entry portion of the extension area SPA, and a region between the intermediate area MCA and the second extension area SPA2. The third input line ILc may electrically connect the first input line ILa to the second input line ILb and be arranged in the intermediate area MCA and the first extension area SPA1. In addition, as shown in FIG. 10, the (1-1)st adjacent area ACA11 may be an entry portion of the first adjacent area ACA1 and a region between the intermediate area MCA and the (1-2)nd adjacent area ACA12. The third input line ILc may electrically connect the first input line ILa to the second input line ILb and be arranged in the intermediate area MCA and the (1-1)st adjacent area ACA11.

In another embodiment, as shown in FIG. 11, the first extension area SPA1 may be an end portion of the extension area SPA, and the second extension area SPA2 may be between the intermediate area MCA and the first extension area SPA1. The third input line ILc may electrically connect the first input line ILa to the second input line ILb and be arranged in the intermediate area MCA, the second extension area SPA2, and the first extension area SPA1. In addition, as shown in FIG. 12, the (1-1)st adjacent area ACA11 may be an end portion of the first adjacent area ACA1, and the (1-2)nd adjacent area ACA12 may be between the intermediate area MCA and the (1-1)st adjacent area ACA11. The third input line ILc may electrically connect the first input line ILa to the second input line ILb and be arranged in the intermediate area MCA, the (1-2)nd adjacent area ACA12, and the (1-1)st adjacent area ACA11.

A pixel configuration structure in the corner area CNA may be the same as or different from a pixel configuration structure in the first display area DA1. The pixel configuration structure may be, for example, an arrangement of the display elements DPE herein. The pixel configuration structure may include pentile Matrix™ structure, a delta structure, an S-stripe structure, a stripe structure, and the like.

In an embodiment, the pixel configuration structure in the intermediate area MCA may be the same as the pixel configuration structure in the first display area DA1. A pixel configuration structure in the central corner area CCA, the first adjacent area ACA1, and the second adjacent area ACA2 may be different from a pixel configuration structure in the first display area DA1. As an example, as shown in FIGS. 9 and 10, the plurality of pixels PX in the first display area DA1 and the intermediate area MCA may be arranged in a pentile Matrix™ structure. The plurality of pixels PX in the extension area SPA and the first adjacent area ACA1 may be arranged in an S-stripe structure.

In another embodiment, a pixel configuration structure in the intermediate area MCA, the second extension area SPA2, and the (1-2)nd adjacent area ACA12 may be the same as a pixel configuration structure in the first display area DA1. A pixel configuration structure in the first extension area SPA1 and the (1-1)st adjacent area ACA11 may be the same as or different from a pixel configuration structure in the first display area DA1. As an example, as shown in FIGS. 11 and 12, the plurality of pixels PX in the first display area DA1, the intermediate area MCA, the second extension area SPA2, and the (1-2)nd adjacent area ACA12 may be arranged in a pentile Matrix™ structure. The plurality of pixels PX in the first extension area SPA1 and the (1-1)st adjacent area ACA11 may be arranged in an S-stripe structure.

A resolution in the corner area CNA may be the same as or different from a resolution in the first display area DA1.

In an embodiment, as shown in FIGS. 9 and 10, a resolution in the intermediate area MCA may be the same as a resolution in the first display area DA1. A resolution in the central corner area CCA, the first adjacent area ACA1, and the second adjacent area ACA2 may be different from a resolution in the first display area DA1. As an example, a resolution in the first display area DA1 and the intermediate area MCA may be higher than a resolution in the extension area SPA and the first adjacent area ACA1. A resolution of the first extension area SPA1 may be the same as a resolution of the second extension area SPA2.

In another embodiment, as shown in FIGS. 11 and 12, a resolution in the intermediate area MCA, the second extension area SPA2, and the (1-2)nd adjacent area ACA12 may be the same as a resolution in the first display area DA1. A resolution in the first extension area SPA1 and the (1-1)st adjacent area ACA11 may be different from a resolution in the first display area DA1. As an example, a resolution in the first display area DA1, the intermediate area MCA, the second extension area SPA2, and the (1-2)nd adjacent area ACA12 may be higher than a resolution in the first extension area SPA1 and the (1-1)st adjacent area ACA11.

In an embodiment, the plurality of pixels PX may include a red pixel, a green pixel, and a blue pixel. In another embodiment, the plurality of pixels PX may include a red pixel, a green pixel, a blue pixel, and a white pixel. The pixel PX may include the pixel circuit PC and the display element DPE connected to the pixel circuit PC. As an example, the display element may be an organic light-emitting diode. Hereinafter, the case where the plurality of pixels PX include a red pixel PXr, a green pixel PXg, and a blue pixel PXb is mainly described. In addition, for convenience of description, the pixel PX arranged in the intermediate area MCA is referred to as a first pixel PX1, the pixel PX arranged in the central corner area CCA, the first adjacent area ACA1, and the second adjacent area ACA2 is referred to as a second pixel PX2, and the pixel PX arranged in the first display area DA1 is referred to as a third pixel PX3.

The first pixel PX1 may be arranged in the intermediate area MCA. The first pixel PX1 may include a first pixel circuit PC1 and a first display element DPE1 connected to the first pixel circuit PC1. The second pixel PX2 may be arranged in the extension area SPA of the central corner area CCA, the first adjacent area ACA1, and the second adjacent area ACA2. The second pixel PX2 may include the second pixel circuit PC2 and a second display element DPE2 connected to the second pixel circuit PC2. The third pixel PX3 may be arranged in the first display area DA1 (the central area CA, the first area A1, and the second area A2). The third pixel PX3 may include a third pixel circuit PC3 and a third display element DPE3 connected to the third pixel circuit PC3.

In some of the first pixels PX1 arranged in the intermediate area MCA, the first display element DPE1 may overlap the first input line ILa, and the first pixel circuit PC1 may be overlapped with the first display element DPE1 of other first pixel PX1 in a plan view. In others of the first pixels PX1 arranged in the intermediate area MCA, the first display element DPE1 may overlap the first pixel circuit PC1 of the corresponding first pixel PX1 in a plan view.

In some of the second pixels PX2 arranged in the extension area SPA, the first adjacent area ACA1, and the second adjacent area ACA2, the second display element DPE2 may overlap at least one of the driving circuit DC, the second input line ILb, and the third input line ILc. The second pixel circuit PC2 may be overlapped with the second display element DPE2 of other second pixel PX2 in a plan view. In others of the second pixels PX2 arranged in the extension area SPA, the first adjacent area ACA1, and the second adjacent area ACA2, the second display element DPE2 may overlap the second pixel circuit PC2 of the corresponding second pixel PX2 and/or the second pixel circuit PC2 of other second pixel PX2 in a plan view.

In the third pixels PX3 arranged in the first display area DA1, the third display element DPE3 may overlap the third pixel circuit PC3 of the corresponding third pixel PX3 and/or the third pixel circuit PC3 of other third pixel PX3 in a plan view.

The driving circuit DC arranged in the first peripheral area AA1 may be configured to supply electrical signals to the third pixel circuits PC3 of the third pixels PX3 arranged in the first display area DA1. The driving circuit DC arranged in the corner area CNA may be configured to supply electrical signals to the third pixel circuits PC3 of the third pixels PX3 arranged in the first display area DA1 and/or the first pixel circuits PC1 of the first pixels PX1 and the second pixel circuits PC2 of the second pixels PX2 arranged in the corner area CNA.

The driving circuit DC may include the plurality of sub-driving circuits SDC. The sub-driving circuits SDC arranged in the extension area SPA, the first adjacent area ACA1, and the second adjacent area ACA2 may each be connected to the first input lines ILa through the second input lines ILb and the third input lines ILc. The sub-driving circuits SDC may each be connected to at least one output line OL. The sub-driving circuits SDC may each be configured to receive signals from the first input lines ILa and output signals to the output line OL.

The output line OL may extend from an output end of the sub-driving circuit SDC to the first display area DA1 and be connected to the pixels PX arranged in a direction from the output end of the sub-driving circuit SDC to the first display area DA1. Some of the output lines OL may be branched. An output branch line OL′ may extend in a direction opposite to the extension direction of the output line OL and be connected to the pixels PX arranged in a direction away from the first display area DA1 from an output end of the sub-driving circuit SDC. As an example, as shown in FIGS. 9 and 10, the output line OL may be connected to the pixels PX arranged in the intermediate area MCA and the first display area DA1, and the output branch line OL′ may be connected to the pixels PX arranged in the extension area SPA, the first adjacent area ACA1, and the second adjacent area ACA2. In addition, as shown in FIGS. 11 and 12, the output line OL may be connected to the pixels PX arranged in the second extension area SPA2, the (1-2)nd adjacent area ACA12, the (2-2)nd adjacent area, the intermediate area MCA, and the first display area DA1. The output branch line OL′ may be connected to the pixels PX arranged in the first extension area SPA1, the (1-1)st adjacent area ACA11, and the (2-1)st adjacent area.

The output line OL may be the gate line GL or the emission control line EL. The driving circuit DC may be apart from the pixel circuit PC of the pixel PX and provided on the same layer as the pixel circuit PC. The sub-driving circuit SDC may be apart from the pixel circuit PC of the pixel PX and provided on the same layer as the pixel circuit PC.

Though FIGS. 9 to 12 show one driving circuit DC, a plurality of driving circuits DC may be arranged over the substrate in another embodiment. As an example, as shown in FIG. 13, a first driving circuit DC1 and a second driving circuit DC2 may be arranged adjacently in the first extension area SPA1, the first adjacent area ACA1, or the second adjacent area ACA2. The first driving circuit DC1 may include a plurality of first sub-driving circuits SDC1, and the second driving circuit DC2 may include a plurality of second sub-driving circuits SDC2. The first sub-driving circuit SDC1 may be configured to receive signals from the first input line ILa through the second input lines ILb and the third input lines ILc, and output signals to a first output line OL1. The second sub-driving circuit SDC2 may be configured to receive signals from the first input line ILa through the second input lines ILb and the third input lines ILc, and output signals to a second output line OL2. In an embodiment, the first sub-driving circuit SDC1 may be a gate driving circuit GDC, the second sub-driving circuit SDC2 may be an emission driving circuit EDC, the first output line OL1 may be the gate line GL, and the second output line OL2 may be the emission control line EL.

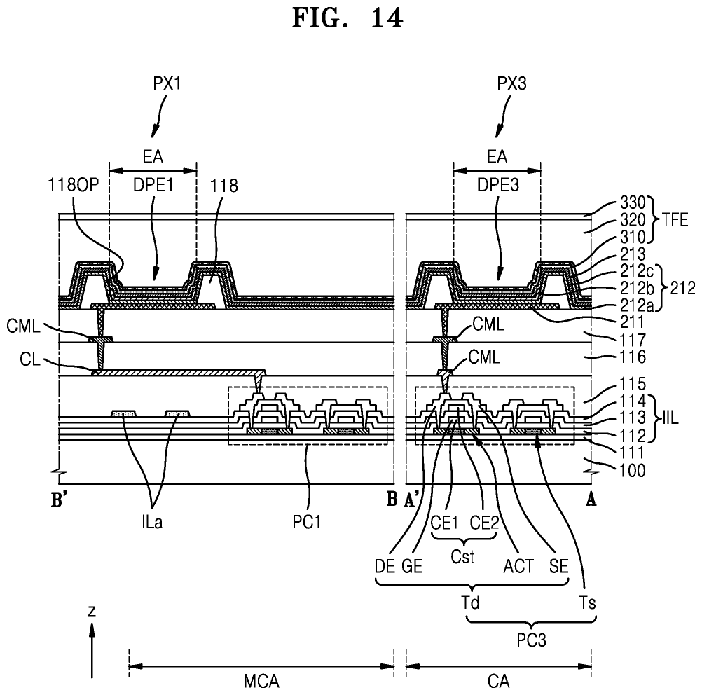

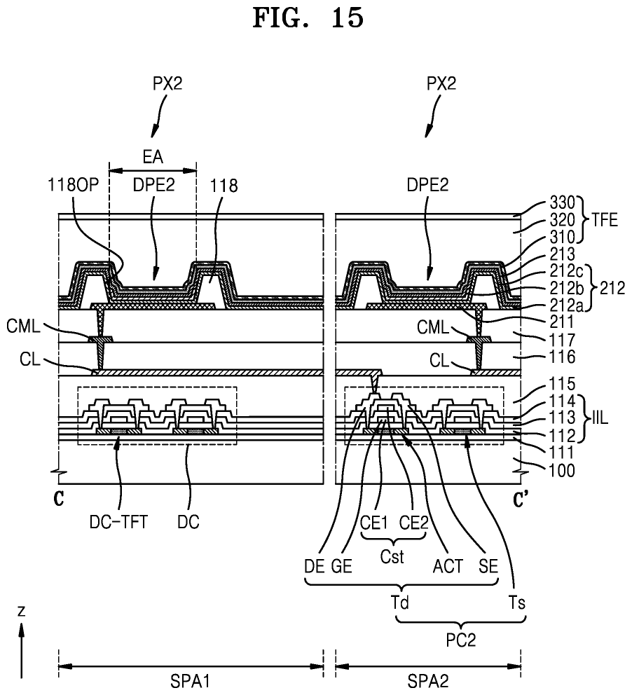

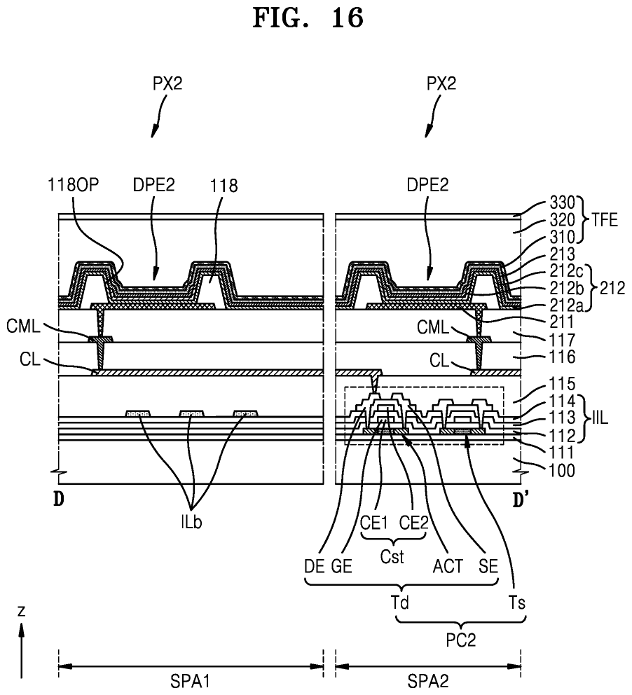

FIG. 14 is a cross-sectional view of the region F taken along lines A-A′ and B-B′ of FIG. 9. FIG. 15 is a cross-sectional view of the region F taken along line C-C′ of FIG. 9. FIG. 16 is a cross-sectional view of the region F taken along line D-D′ of FIG. 9.

Referring to FIGS. 14 to 16, the display panel may include a substrate 100. A buffer layer 111 may be disposed on the substrate 100. The buffer layer 111 may include an inorganic insulating material such as silicon nitride (SiNₓ), silicon oxynitride (SiOₓN_{y}), and silicon oxide (SiOₓ), and include a single layer or a multi-layer including the inorganic insulating materials.

The pixel circuit PC may be disposed on the buffer layer 111. The pixel circuit PC may include the first pixel circuit PC1, the second pixel circuit PC2, and the third pixel circuit PC3, where the first pixel circuit PC1 is arranged in the intermediate area MCA, the second pixel circuit PC2 is arranged in the extension area SPA, the first adjacent area ACA1, and the second adjacent area ACA2, and the third pixel circuit PC3 is arranged in the first display area DA1. Each of the first pixel circuit PC1, the second pixel circuit PC2, and the third pixel circuit PC3 may include a driving thin-film transistor Td, a switching thin-film transistor Ts, and a capacitor Cst. The capacitor Cst may overlap the driving thin-film transistor Td in a plan view. In an embodiment, the capacitor Cst may not overlap the driving thin-film transistor Td in a plan view. The driving thin-film transistor Td and the switching thin-film transistor Ts may each include a semiconductor layer ACT, a gate electrode GE, a source electrode SE, and a drain electrode DE.

The driving circuit DC may be disposed on the buffer layer 111. The driving circuit DC may include at least one driving circuit thin-film transistor DC-TFT. The driving circuit thin-film transistor DC-TFT may include a semiconductor layer ACT, a gate electrode GE, a source electrode SE, and a drain electrode DE.

The semiconductor layer ACT may include polycrystalline silicon. Alternatively, the semiconductor layer ACT may include amorphous silicon, an oxide semiconductor, or an organic semiconductor. The semiconductor layer ACT may include a channel region, a drain region, and a source region, the drain region and the source region being on two opposite sides of the channel region. The gate electrode GE may overlap the channel region in a plan view.

The gate electrode GE may include a conductive material including molybdenum (Mo), aluminum (Al), copper (Cu), and titanium (Ti) and have a single-layered structure or a multi-layered structure including the above materials.

A first gate insulating layer 112 between the semiconductor layer ACT and the gate electrode GE may include an inorganic insulating material including silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnOₓ, which may be ZnO and/or ZnO₂).

A second gate insulating layer 113 may cover the gate electrode GE. Similar to the first gate insulating layer 112, the second gate insulating layer 113 may include an inorganic insulating material including silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnOₓ, which may be ZnO and/or ZnO₂c).

An upper electrode CE2 of the capacitor Cst may be disposed on the second gate insulating layer 113. The upper electrode CE2 may overlap the gate electrode GE of the driving thin-film transistor Td therebelow. The gate electrode GE of the driving thin-film transistor Td may serve as a lower electrode CE1 of the capacitor Cst. The upper electrode CE2 may include aluminum (Al), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and include a single layer or a multi-layer including the above materials.

An interlayer-insulating layer 114 may cover the upper electrode CE2. The interlayer-insulating layer 114 may include an inorganic insulating material including silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnOₓ, which may be ZnO and/or ZnO₂). The interlayer-insulating layer 114 may include a single layer or a multi-layer including the inorganic insulating material.

Though not shown, the gate line GL and the emission control line EL may be disposed between the first gate insulating layer 112 and the second gate insulating layer 113 and/or between the second gate insulating layer 113 and the interlayer-insulating layer 114.

The drain electrode DE and the source electrode SE may each be disposed on the interlayer-insulating layer 114. The drain electrode DE and the source electrode SE may each include a conductive material including molybdenum (Mo), aluminum (Al), copper (Cu), and titanium (Ti) and include a single layer or a multi-layer including the above materials. In an embodiment, the drain electrode DE and the source electrode SE may each have a multi-layered structure of Ti/Al/Ti.

The first input line ILa and the second input line ILb may be disposed on the interlayer-insulating layer 114. The first input line ILa and the second input line ILb may each include a conductive material including molybdenum (Mo), aluminum (Al), copper (Cu), and titanium (Ti) and include a single layer or a multi-layer including the above materials. In another embodiment, the first input line ILa and the second input line ILb may be disposed between the first gate insulating layer 112 and the second gate insulating layer 113 and/or between the second gate insulating layer 113 and the interlayer-insulating layer 114.

The first gate insulating layer 112, the second gate insulating layer 113, and the interlayer-insulating layer 114 may be referred to as inorganic insulating layers IIL.

A first insulating layer 115 may cover the drain electrode DE and the source electrode SE. The first insulating layer 115 may include an organic insulating material. As an example, the first insulating layer 115 may include an organic insulating material including a general-purpose polymer such as polymethylmethacrylate (“PMMA”) or polystyrene (“PS”), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

A connection electrode CML and a connection line CL may be disposed on the first insulating layer 115. The connection electrode CML and the connection line CL may be connected to the drain electrode DE or the source electrode SE through a contact hole in the first insulating layer 115. The connection electrode CML and the connection line CL may each include a conductive material including molybdenum (Mo), aluminum (Al), copper (Cu), and titanium (Ti) and include a single layer or a multi-layer including the above materials. In an embodiment, the connection electrode CML may have a multi-layered structure of Ti/Al/Ti.

A second insulating layer 116 may cover the connection electrode CML and the connection line CL. The second insulating layer 116 may include an organic insulating layer. The second insulating layer 116 may include an organic insulating material including a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

The connection electrode CML may be disposed on the second insulating layer 116. The connection electrode CML may be connected to the connection electrode CML or the connection line CL therebelow through a contact hole in the second insulating layer 116. The connection electrode CML may include a conductive material including molybdenum (Mo), aluminum (Al), copper (Cu), and titanium (Ti) and have a single-layered structure or a multi-layered structure including the above materials. In an embodiment, the connection electrode CML may have a multi-layered structure of Ti/Al/Ti. Though not shown, a data line, a driving voltage line, and the like may be further disposed on the second insulating layer 116.

A third insulating layer 117 may be disposed on the second insulating layer 116. The third insulating layer 117 may include an organic insulating layer. The third insulating layer 117 may include an organic insulating material including a general-purpose polymer such as polymethylmethacrylate (PMMA) or polystyrene (PS), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

The display element DPE may be disposed on the third insulating layer 117. The display element DPE may include the first display element DPE1, the second display element DPE2, and the third display element DPE3, where the first display element DPE1 is arranged in the intermediate area MCA, the second display element DPE2 is arranged in the extension area SPA, the first adjacent area ACA1, and the second adjacent area ACA2, and the third display element DPE3 is arranged in the first display area DA1. The first display element DPE1, the second display element DPE2, and the third display element DPE3 may each be the organic light-emitting diode OLED. The first display element DPE1, the second display element DPE2, and the third display element DPE3 may each include a pixel electrode 211, an intermediate layer 212, and an opposite electrode 213.

The pixel electrode 211 may be disposed on the third insulating layer 117. The pixel electrode 211 may be connected to the driving thin-film transistor Td through the connection electrode CM and/or the connection line CL, or connected to the driving thin-film transistor Td through another switching thin-film transistor Ts connected to the connection electrode CML.

The first display element DPE1 of the first pixel PX1 arranged in the intermediate area MCA may partially overlap or may not overlap the first pixel circuit PC1 in a plan view. As shown in FIG. 14, as an example, the first display element DPE1 may overlap the first input line ILa and may not overlap the first pixel circuit PC1 in a plan view, and may be electrically connected to the first pixel circuit PC1 through the connection electrode CML and/or the connection line CL. The third display element DPE3 may partially overlap the third pixel circuit PC3 and may be electrically connected to the third pixel circuit PC3 through the connection electrodes CML in a plan view.

The second display element DPE2 arranged in the first extension area SPA1, the (1-1)st adjacent area ACA11, and the (2-1)st adjacent area may partially overlap the second pixel circuit PC2 or may not overlap the second pixel circuit PC2 in a plan view.

As an example, the second display element DPE2 shown in FIG. 15 may overlap the driving circuit DC, and the second pixel circuit PC2 is arranged in the second extension area SPA2, the (1-2)nd adjacent area ACA12, or the (2-2)nd adjacent area in a plan view.

As an example, the second display element DPE2 shown in FIG. 16 may overlap the second input line ILb, and the second pixel circuit PC2 is arranged in the second extension area SPA2, the (1-2)nd adjacent area ACA12, or the (2-2)nd adjacent area in a plan view. The second display element DPE2 may be electrically connected to the second pixel circuit PC2 through the connection electrode CML and/or the connection line CL. The connection line CL of the extension area SPA may extend from the first extension area SPA1 to the second extension area SPA2. The connection line CL of the first adjacent area ACA1 may extend from the (1-1)st adjacent area ACA11 to the (1-2)nd adjacent area ACA12. The connection line CL of the (2-1)st adjacent area may extend from the (2-1)st adjacent area to the (2-2)nd adjacent area.

The second display element DPE2 arranged in the second extension area SPA2, the (1-2)nd adjacent area ACA12, and the (2-2)nd adjacent area may partially overlap the second pixel circuit PC2 or may not overlap the second pixel circuit PC2 in a plan view. The second display element DPE2 arranged in the second extension area SPA2, the (1-2)nd adjacent area ACA12, and the (2-2)nd adjacent area may be electrically connected to the second pixel circuit PC2 arranged in the second extension area SPA2, the (1-2)nd adjacent area ACA12, and the (2-2)nd adjacent area through the connection electrode CM and/or the connection line CL.

The pixel electrode 211 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In another embodiment, the pixel electrode 211 may include a reflective layer including silver (Ag), magnesium (Mg), aluminum (Al), platinum (Pt), palladium (Pd), gold (Au), nickel (Ni), neodymium (Nd), iridium (Ir), chrome (Cr), or a compound thereof. In another embodiment, the pixel electrode 211 may further include a layer on/under the reflective layer, the layer including ITO, IZO, ZnO, or In₂O₃.

A pixel-defining layer 118 may be disposed on the pixel electrode 211, where the pixel-defining layer 118 includes an opening 1180P exposing a portion of the pixel electrode 211. The pixel-defining layer 118 may include an organic insulating material and/or an inorganic insulating material. The opening 1180P may define an emission area EA of light emitted from the display element. As an example, the width of the opening 1180P may correspond to the width of the emission area EA.

The intermediate layer 212 may be disposed on the pixel-defining layer 118. The intermediate layer 212 may include an emission layer 212b disposed in the opening 1180P of the pixel-defining layer 118. The emission layer 212b may include a polymer or low-molecular weight organic material emitting light of a preset color.

A first functional layer 212a and a second functional layer 212c may be disposed under and on the emission layer 212b, respectively. The first functional layer 212a may include, for example, a hole transport layer (“HTL”), or include an HTL and a hole injection layer (“HIL”). The second functional layer 212c is an element disposed on the emission layer 212b and may be optional. The second functional layer 212c may include an electron transport layer (“ETL”) and/or an electron injection layer (“EIL”). Like the opposite electrode 213 described below, the first functional layer 212a and/or the second functional layer 212c may be common layers covering the substrate 100 entirely.

The opposite electrode 213 may include a conductive material having a low work function. As an example, the opposite electrode 213 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof.

Alternatively, the opposite electrode 213 may further include a layer on the (semi) transparent layer, the layer including ITO, IZO, ZnO, or In₂O₃.

In an embodiment, a capping layer (not shown) may be further arranged on the opposite electrode 213. The capping layer may include an inorganic material (e.g., lithium fluoride (LiF)), and/or an organic material.

A thin-film encapsulation layer TFE may be disposed on the opposite electrode 213. In an embodiment, the thin-film encapsulation layer TFE may include at least one inorganic encapsulation layer and at least one organic encapsulation layer. As an example, the thin-film encapsulation layer TFE may include a first inorganic encapsulation layer 310, an organic encapsulation layer 320, and a second inorganic encapsulation layer 330 that are sequentially stacked.

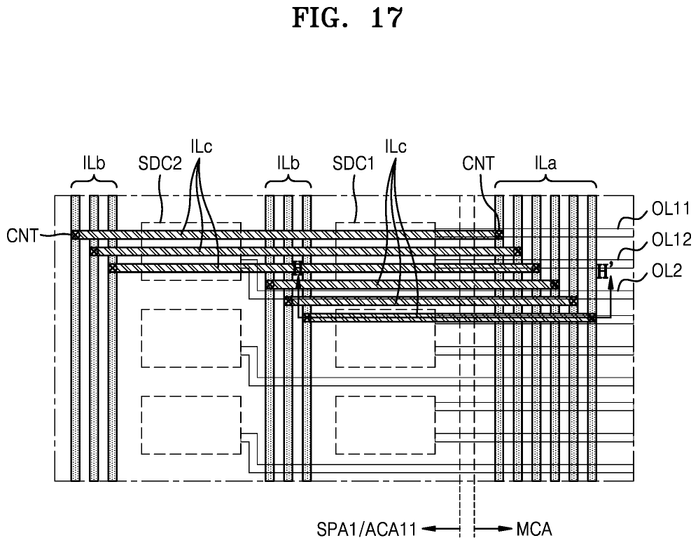

FIGS. 17 to 19 are schematic views of an input line in the corner area.

Referring to FIG. 17, the first input line ILa and the second input line ILb may extend in one direction (e.g., vertical direction in FIG. 17). The third input line ILc may extend in a direction (e.g., horizontal direction in FIG. 17) different from the directions of the first input line ILa and the second input line ILb. The third input line ILc may connect the first input line ILa to the second input line ILb. The driving circuit DC may be disposed between the first input line ILa and the second input line ILb in a plan view. The driving circuit DC may include the plurality of sub-driving circuits SDC1 and SDC2. The first sub-driving circuit SDC1 may be connected to first output lines OL11 and OL12, and the second sub-driving circuit SDC2 may be connected to the second output line OL2. In an embodiment, the first output lines OL11 and OL12 may be gate lines, and the second output line OL2 may be an emission control line.

The first input line ILa may be disposed in the same layer as the second input line ILb. The third input line ILc may be disposed in a layer different from the first input line ILa and the second input line ILb. Some of the third input lines ILc may overlap both the first sub-driving circuit SDC1 and the second sub-driving circuit SDC2 in a plan view. Some of the third input lines ILc may overlap the first sub-driving circuit SDC1 in a plan view.

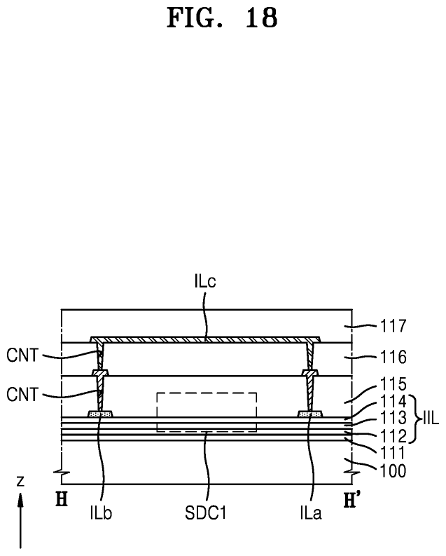

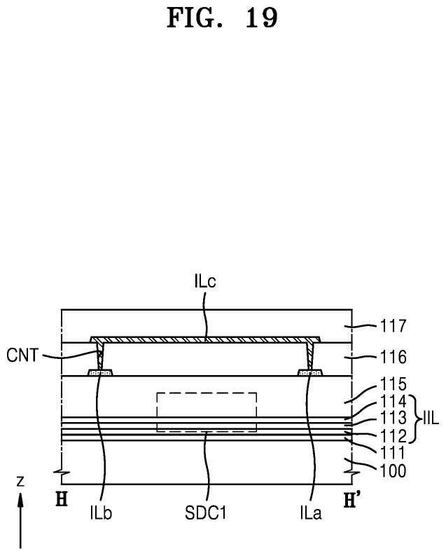

FIG. 18 is a schematic cross-sectional view of the corner area of FIG. 17, taken along line H-H′, and FIG. 19 is another schematic cross-sectional view of the corner area of FIG. 17, taken along line H-H′. In an embodiment, as shown in FIG. 18, the first input line ILa and the second input line ILb may be disposed on the interlayer-insulating layer 114, and the third input line ILc may be disposed on the second insulating layer 116. The third input line ILc may be electrically connected to the first input line ILa and the second input line ILb by contacting the first input line ILa and the second input line ILb through contact holes CNT of the second insulating layer 116 and the first insulating layer 115. In another embodiment, as shown in FIG. 19, the first input line ILa and the second input line ILb may be disposed on the first insulating layer 115, and the third input line ILc may be disposed on the second insulating layer 116. The third input line ILc may be electrically connected to the first input line ILa and the second input line ILb by contacting the first input line ILa and the second input line ILb through contact holes CNT of the second insulating layer 116.

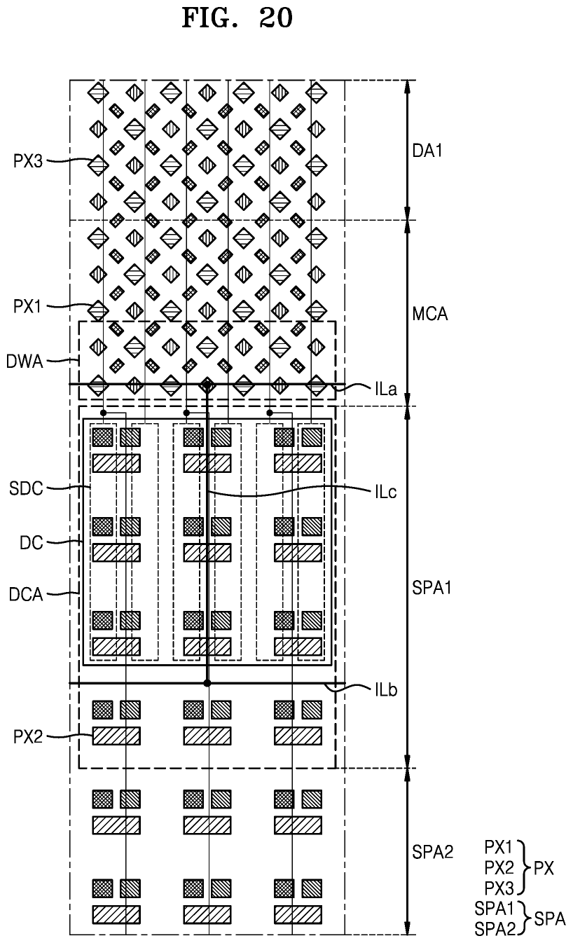

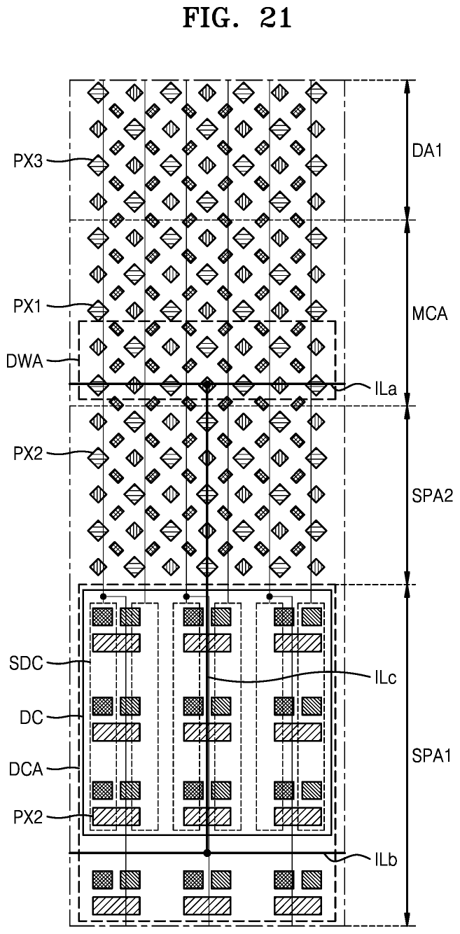

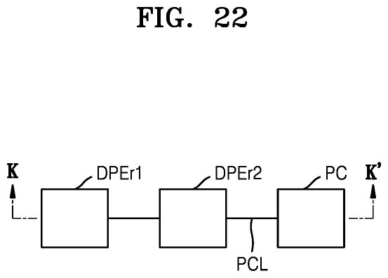

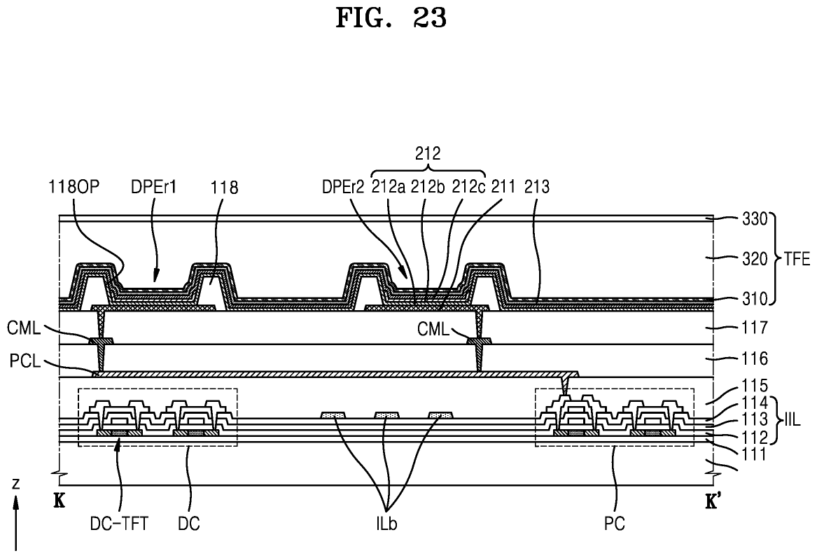

FIGS. 20 and 21 are schematic views of a portion of a display panel. FIGS. 22 and 23 are schematic views of pixels in a driving circuit area DCA of FIGS. 20 and 21.

As shown in FIG. 20, a pixel configuration structure of the first pixels PX1 in the intermediate area MCA may be the same as a pixel configuration structure of the third pixels PX3 in the first display area DA1, and a pixel configuration structure of the second pixels PX2 in the extension area SPA may be different from a pixel configuration structure of the third pixels PX3 in the first display area DA1. As shown in FIG. 21, a pixel configuration structure of the first pixels PX1 in the intermediate area MCA and a pixel configuration structure of the second pixels PX2 in the second extension area SPA2 may each be the same as a pixel configuration structure of the third pixels PX3 in the first display area DA1, and a pixel configuration structure of the second pixels PX2 in the first extension area SPA1 may be different from a pixel configuration structure of the third pixels PX3 in the first display area DA1.

The intermediate area MCA may include a wiring area DWA in which the first input lines ILa are arranged, and the first extension area SPA1 may include the driving circuit area DCA in which the driving circuit DC and the second input lines ILb are arranged. In an embodiment, as shown in FIG. 20, the driving circuit area DCA may be arranged between the intermediate area MCA and the second extension area SPA2. In this case, the third input line ILc may pass across the driving circuit area DCA. In another embodiment, as shown in FIG. 21, the second extension area SPA2 may be arranged between the driving circuit area DCA and the intermediate area MCA. In this case, the third input line ILc may pass across the second extension area SPA2, and the driving circuit area DCA.

In an embodiment, the pixels PX arranged in the wiring area DWA and the driving circuit area DCA may be configured to share the pixel circuit PC. Display elements of pixels configured to emit light of the same color may be driven in common by one pixel circuit PC. A plurality of display elements driven in common by one pixel circuit PC may be electrically connected to each other. The pixel circuit PC may be arranged near the display elements. The pixel circuit PC may be partially overlapped with one of the display elements in a plan view. As an example, as shown in FIG. 22, a first red display element DPEr1 and a second red display element DPEr2 may be electrically connected to one pixel circuit PC by a conductive layer PCL. The first red display element DPEr1 and the second red display element DPEr2 may be configured to emit light by one pixel circuit PC.

As shown in FIG. 23, the conductive layer PCL may electrically connect the pixel electrode 211 of the first red display element DPEr1 and the pixel electrode 211 of the second red display element DPEr2. In an embodiment, the conducive layer PCL may be disposed on the first insulating layer 115, electrically connected to the pixel electrodes 211 on the third insulating layer 117 through the connection electrode CML on the second insulating layer 116, and electrically connected to the pixel circuit PC therebelow. In another embodiment, the conductive layer PCL may be disposed on the second insulating layer 116, electrically connected to the pixel electrodes 211 on the third insulating layer 117, and electrically connected to the pixel circuit PC through the connection electrode CML on the first insulating layer 115.

The conductive layer PCL, the first red display element DPEr1, and the second red display element DPEr2 may overlap the driving circuit DC and/or the second input line ILb in the driving circuit area DCA in a plan view. The conductive layer PCL, the first red display element DPEr1, and the second red display element DPEr2 may overlap the first input line ILa in the wiring area DWA in a plan view. FIG. 23 shows an example in which the conductive layer PCL, the first red display element DPEr1, and the second red display element DPEr2 overlap the driving circuit DC and the second input line ILb in a plan view.

According to an embodiment, because the driving circuit is arranged in a cut portion (e.g., the extension area and the adjacent area of the second corner area) in the corner area, a pixel configuration structure and a resolution of the first corner area (e.g., the intermediate area) is implemented to be the same as a pixel configuration structure and a resolution of the main display area, and thus, visibility that occurs at the boundary between the main display area and the corner area may be improved. The driving circuit may be located in the entry portion or the end portion of the cut portion. When the position of the driving circuit in the corner area is away from the main display area, a region of the corner area that has the same pixel configuration structure and same resolution as a pixel configuration structure and a resolution of the main display area may increase.

Embodiments may provide a display panel and a display apparatus, capable of improving visibility in the corner area.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display panel comprising:
a substrate including a main display area and a corner area extending from a corner of the main display area, wherein the corner area includes a first corner area and a second corner area, the first corner area is adjacent to the main display area, and the second corner area is outside the first corner area;
a first input line arranged in the first corner area;
a second input line arranged in the second corner area;
a third input line connecting the first input line to the second input line;
a first pixel circuit and a first display element connected to the first pixel circuit, each arranged in the first corner area;
a second pixel circuit and a second display element connected to the second pixel circuit, each arranged in the second corner area; and
a driving circuit arranged in the second corner area, connected to the second input line, and configured to supply electrical signals to the first pixel circuit and the second pixel circuit.

2. The display panel of claim 1, wherein the second corner area includes a plurality of extension areas apart from each other,
each of the plurality of extension areas is divided into a first extension area and a second extension area, and
the driving circuit is arranged in the first extension area.

3. The display panel of claim 2, wherein the first extension area is between the first corner area and the second extension area.

4. The display panel of claim 3, wherein a resolution of the first extension area is less than a resolution of the first corner area and is equal to a resolution of the second extension area.

5. The display panel of claim 4, wherein a resolution of the main display area is equal to the resolution of the first corner area.

6. The display panel of claim 2, wherein an arrangement of the first display element in the first corner area is the same as an arrangement of a display element in the main display area and the same as or different from an arrangement of the second display element in the extension area.

7. The display panel of claim 2, wherein the second extension area is between the first corner area and the first extension area.

8. The display panel of claim 7, wherein a resolution of the first extension area is less than a resolution of the first corner area, and a resolution of the second extension area is equal to the resolution of the first corner area.

9. The display panel of claim 8, wherein a resolution of the main display area is equal to the resolution of the first corner area.

10. The display panel of claim 7, wherein an arrangement of the first display element in the first corner area is the same as an arrangement of a display element in the main display area, the same as an arrangement of the second display element in the second extension area, and the same as or different from an arrangement of the second display element in the first extension area.

11. The display panel of claim 2, wherein a plurality of second display elements are arranged in the extension area, and
pixel electrodes of some of the plurality of second display elements arranged in the first extension area are electrically connected to each other.

12. The display panel of claim 1, wherein the first input line is disposed in a same layer as the second input line and disposed in a layer different from the third input line.

13. The display panel of claim 1, wherein the first display element overlaps the first input line.

14. The display panel of claim 1, wherein the second display element overlaps the driving circuit.

15. The display panel of claim 1, wherein the second display element overlaps the second input line.

16. The display panel of claim 1, wherein a plurality of first display elements are arranged in the first corner area, and
pixel electrodes of some of the plurality of first display elements arranged in the first corner area are electrically connected to each other.

17. A display panel including a first display area and a second display area,
wherein the first display area includes a central area, a first area, and a second area, the first area is adjacent to the central area in a first direction, and the second area is adjacent to the central area in a second direction crossing the first direction, and
the second display area includes a corner area between the first area and the second area, the corner area includes a first corner area and a second corner area, the first corner area is adjacent to the first display area, and the second corner area is outside the first corner area,
the display panel comprises:
a first input line arranged in a peripheral area and the first corner area, the peripheral area being outside the first area;
a second input line arranged in the second corner area;
a third input line connecting the first input line to the second input line;
a first driving circuit arranged in the peripheral area, connected to the first input line, and configured to supply electrical signals to a pixel circuit in the first display area; and
a second driving circuit arranged in the second corner area, connected to the second input line, and configured to supply electrical signals to a pixel circuit in the first corner area, and a pixel circuit in the second corner area.

18. The display panel of claim 17, wherein the second corner area includes a plurality of extension areas apart from each other,
each of the plurality of extension areas is divided into a first extension area and a second extension area, and
the second driving circuit is arranged in the first extension area.

19. The display panel of claim 18, wherein the first extension area is between the first corner area and the second extension area.

20. The display panel of claim 18, wherein the second extension area is between the first corner area and the first extension area.
